(19) United States
(12) Patent Application Publication
(10) Pub. No.: US 2024/0215333 A1
(43) Pub. Date: Jun. 27, 2024

(54) Display Substrate and Preparation Method thereof, and Display Apparatus

(71) Applicant: BOE Technology Group Co., Ltd., Beijing (CN)

(72) Inventors: Pinfan WANG, Beijing (CN); Zunqing SONG, Beijing (CN); Fangxu CAO, Beijing (CN); Jia ZHAO, Beijing (CN)

(21) Appl. No.: 17/912,862

(22) PCT Filed: Nov. 19, 2021
(86) PCT No.: PCT/CN2021/131590

§ 371 Date: Sep. 20, 2022

(30) Foreign Application Priority Data
May 27, 2021 (CN) 202110587584.7

(51) Int. Cl. H10K 59/124; H10K 59/12; H10K 59/80; H10K 77/10

(52) U.S. Cl. CPC H10K 59/124; H10K 59/1201; H10K 59/8731; H10K 77/111

(57) ABSTRACT

The present disclosure provides a display substrate and a preparation method thereof, and a display apparatus. The display substrate includes a pixel region and a stretch hole region which includes a hole region and a partition region; the display substrate includes a base substrate, a structure layer, and an encapsulation structure layer and the partition region includes at least one partition structure surrounding the hole region; the hole region includes a base substrate hole disposed on the base substrate and a structure hole penetrating through the structure layer, the base substrate hole is communicated with the structure hole, at least a portion of an inner wall of the structure hole is covered by at least one encapsulation material layer in the encapsulation structure layer, and an inner wall of the base substrate hole includes a base substrate material segment that is not covered by the encapsulation material layer.

### CROSS-REFERENCE TO RELATED APPLICATIONS

The present application is a U.S. National Phase Entry of International Application No. PCT/CN2021/131590 having an international filing date of Nov. 19, 2021, which claims priority to Chinese Patent Application No. 202110587584.7 filed to the CNIPA on May 27, 2021 and entitled “Display Substrate and Preparation Method thereof, and Display Apparatus”. The entire contents of the above-identified applications are hereby incorporated into the present application by reference.

### TECHNICAL FIELD

The present disclosure relates to, but is not limited to, the field of display technologies, and in particular to a display substrate and preparation method thereof, and a display apparatus.

### BACKGROUND

An Organic Light Emitting Diode (OLED for short) is an active light emitting display device, which has advantages of auto-luminescence, a wide viewing angle, a high contrast ratio, low power consumption, an extremely high response speed, lightness and thinness, bendability, and a low cost, etc. With constant development of display technologies, a flexible display apparatus (Flexible Display) using an OLED as a light emitting device and performing signal control using a Thin Film Transistor (TFT for short) has become a mainstream product in the field of display at present.

### SUMMARY

The following is a summary of subject matters described herein in detail. The summary is not intended to limit the protection scope of claims.

In one aspect, the present disclosure provides a display substrate including a pixel region and a stretch hole region, the pixel region includes at least one sub-pixel, and the stretch hole region includes at least one hole region and a partition region surrounding the hole region; the display substrate includes a base substrate, a structure layer disposed on the base substrate, and an encapsulation structure layer disposed on a side of the structure layer away from the base substrate, the partition region includes at least one partition structure, the partition structure surrounds the hole region; the hole region includes a base substrate hole disposed on the base substrate and a structure hole penetrating through the structure layer, the base substrate hole is communicated with the structure hole, at least a portion of an inner wall of the structure hole is covered by at least one encapsulation material layer in the encapsulation structure layer, and an inner wall of the base substrate hole includes a base substrate material segment that is not covered by the encapsulation material layer.

In an exemplary implementation mode, the inner wall of the base substrate hole further includes an encapsulation material segment covered by the encapsulation material layer, wherein the encapsulation material segment is located on a side of the base substrate material segment close to the structure hole.

In an exemplary implementation mode, the base substrate hole includes a through hole penetrating through the base substrate, or includes a blind hole not penetrating through the base substrate.

In an exemplary implementation mode, the partition structure includes a first partition layer surrounding the hole region and a second partition layer disposed on a side of the first partition layer away from the base substrate, the first partition layer is provided with a first partition hole surrounding the hole region, the second partition layer is provided with a second partition hole surrounding the hole region, and the second partition hole is communicated with the first partition hole to form a partition groove; the second partition layer located around the second partition hole has a protruding part relative to a sidewall of the first partition hole, and the protruding part and the sidewall of the first partition hole form an inwardly recessed structure.

In an exemplary implementation mode, the partition structure is disposed between the structure layer and the encapsulation structure layer.

In an exemplary implementation mode, an opening size of the base substrate hole is smaller than an opening size of the structure hole.

In an exemplary implementation mode, the encapsulation structure layer includes a first encapsulation layer, the first encapsulation layer covers the structure layer and the partition structure, an encapsulation hole is provided on the first encapsulation layer of the hole region, and the encapsulation hole is communicated with the structure hole.

In an exemplary implementation mode, an orthographic projection of an inner wall of the encapsulation hole on the base substrate and an orthographic projection of an inner wall of the structure hole on the base substrate are substantially overlapped.

In an exemplary implementation mode, the encapsulation structure layer further includes a second encapsulation layer; the second encapsulation layer is disposed on a side of the first encapsulation layer of the pixel region away from the base substrate, or the second encapsulation layer is disposed on a side of the first encapsulation layer of the pixel region and the partition region away from the base substrate.

In an exemplary implementation mode, the encapsulation structure layer further includes a third encapsulation layer as the encapsulation material layer; the third encapsulation layer is disposed on a side of the second encapsulation layer away from the base substrate, the third encapsulation layer covers inner walls of the structure hole and the encapsulation hole, and the third encapsulation layer does not cover the base substrate material segment of the base substrate hole.

In an exemplary implementation mode, the third encapsulation layer covers a part of an inner wall of the base substrate hole, and an encapsulation material segment covered by the third encapsulation layer is formed in the base substrate hole, or the third encapsulation layer does not cover the inner wall of the base substrate hole, and the inner wall of the base substrate hole is all the base substrate material segment.

In an exemplary implementation mode, an emitting block is provided on a side of the structure layer of the hole region away from the base substrate, an emitting block hole is provided on the emitting block, the emitting block hole is communicated with the structure hole, and the third encapsulation layer covers an inner wall of the emitting block hole.

In an exemplary implementation mode, a cathode block is disposed on a side of the emitting block of the hole region away from the base substrate, the first encapsulation layer is disposed on a side of the cathode block away from the base substrate, a cathode block hole is provided on the cathode block, the cathode block hole is communicated with the emitting block hole and the encapsulation hole, and the third encapsulation layer covers an inner wall of the cathode block hole.

In another aspect, the present disclosure further provides a display apparatus, including the aforementioned display substrate.

In yet another aspect, the present disclosure further provides a preparation method of a display substrate. The display substrate includes a pixel region and a stretch hole region, the pixel region includes at least one sub-pixel, and the stretch hole region includes at least one hole region and a partition region surrounding the hole region; the preparation method includes: forming a base substrate, a structure layer disposed on the base substrate, and an encapsulation structure layer disposed on the structure layer, wherein the partition region includes at least a partition structure, and the partition structure surrounds the hole region; and forming a stretch hole in the hole region, wherein the stretch hole region includes a base substrate hole disposed on the base substrate and a structure hole penetrating through the structure layer, the base substrate hole is communicated with the structure hole, at least a portion of an inner wall of the structure hole is covered by at least one encapsulation material layer in the encapsulation structure layer, and an inner wall of the base substrate hole includes a base substrate material segment that is not covered by the encapsulation material layer.

In an exemplary implementation mode, the inner wall of the base substrate hole further includes an encapsulation material segment covered by the encapsulation material layer, and the encapsulation material segment is located on a side of the base substrate material segment close to the structure hole.

In an exemplary implementation mode, the base substrate hole includes a through hole penetrating through the base substrate, or includes a blind hole not penetrating through the base substrate.

In an exemplary implementation mode, the forming the stretch hole in the hole region includes: forming an encapsulation structure layer and a transition hole; the encapsulation structure layer includes a first encapsulation layer, a second encapsulation layer, and a third encapsulation layer as the encapsulation material layer that are stacked; the transition hole is located in the hole region, the first encapsulation layer and the structure layer in the transition hole are removed, and the third encapsulation layer covers an inner wall of the transition hole; and etching the transition hole to form a stretch hole; the stretch hole includes the transition hole and a base substrate hole disposed on the base substrate, the base substrate hole and the transition hole are communicated, and an inner wall of the base substrate hole includes a base substrate material segment not covered by the third encapsulation layer.

In an exemplary implementation mode, materials of the first encapsulation layer and the third encapsulation layer include inorganic materials, and a material of the second encapsulation layer includes an organic material; the forming the encapsulation structure layer and the transition hole includes: forming a first encapsulation layer, wherein the first encapsulation layer covers the structure layer and the partition structure; forming a transition hole in the hole region through a patterning process, wherein the first encapsulation layer and the structure layer in the transition hole are removed; forming a second encapsulation layer, wherein the second encapsulation layer is disposed on a side of the first encapsulation layer of the pixel region and the partition region away from the base substrate, or, a first organic material layer in the second encapsulation layer is disposed on a side of the first encapsulation layer of the pixel region away from the base substrate, and a second organic material layer in the second encapsulation layer is disposed on a side of the first encapsulation layer of the partition region away from the base substrate; and forming a third encapsulation layer as the encapsulation material layer, wherein the third encapsulation layer is provided on a side of the second encapsulation layer away from the base substrate, and the third encapsulation layer covers the inner wall of the transition hole.

Other aspects may be understood upon reading and understanding drawings and detailed description.

### BRIEF DESCRIPTION OF DRAWINGS

Accompanying drawings are used for providing a further understanding of technical solutions of the present disclosure, constitute a part of the specification, and together with embodiments of the present disclosure, are used for explaining the technical solutions of the present disclosure but not to constitute limitations on the technical solutions of the present disclosure. Shapes and sizes of various components in the drawings do not reflect actual scales, and are only intended to schematically illustrate contents of the present disclosure.

FIG. 1 is a schematic diagram of a structure of a display substrate.

FIG. 2 is a schematic diagram of a planar structure of a display substrate.

FIG. 3 is a schematic diagram of an equivalent circuit of an OLED pixel drive circuit.

FIG. 4 is a working timing diagram of a pixel drive circuit.

FIG. 5 is a schematic diagram of a cross-sectional structure of a display substrate according to an exemplary embodiment of the present disclosure.

FIG. 6 is a schematic diagram after a pattern of a pixel drive circuit is formed according to an embodiment of the present disclosure.

FIG. 7 is a schematic diagram after patterns of a second planarization layer and a partition structure are formed according to an embodiment of the present disclosure.

FIG. 8 is a schematic diagram after a pattern of an anode is formed according to an embodiment of the present disclosure.

FIG. 9 is a schematic diagram after a pattern of a pixel definition layer is formed according to an embodiment of the present disclosure.

FIG. 10 is a schematic diagram after patterns of an organic emitting layer and an emitting block are formed according to an embodiment of the present disclosure.

FIG. 11 is a schematic diagram after patterns of a cathode and a cathode block are formed according to an embodiment of the present disclosure.

FIG. 12 is a schematic diagram after a pattern of a first encapsulation thin film is formed according to an embodiment of the present disclosure.

FIGS. 13a and 13b are schematic diagrams after a pattern of a transition hole is formed according to an embodiment of the present disclosure.

FIGS. 14a and 14b are schematic diagrams after a pattern of a second encapsulation layer is formed according to an embodiment of the present disclosure.

FIGS. 15a and 15b are schematic diagrams after a pattern of a third encapsulation layer is formed according to an embodiment of the present disclosure.

FIGS. 16a to 16d are schematic diagrams after a pattern of a stretch hole is formed according to an embodiment of the present disclosure.

Reference signs are explained below.

| | | |
|---|---|---|
| 1-glass carrier plate; | 10-base substrate; | 11-first active layer; |
| 12-first gate electrode; | 13-first source electrode; | 14-first drain electrode; |
| 15-connection electrode; | 20-drive structure layer; | 21-first capacitor electrode; |
| 22-second capacitor | 30-structure layer; | 31-first planarization layer; |
| electrode; | | |
| 32-second planarization layer; | 33-inorganic layer; | 41-first partition layer; |
| 42-second partition layer; | 50-hole region; | 51-partition region; |
| 60-partition groove; | 70-emitting structure layer; | 71-anode; |
| 72-pixel definition layer; | 73-organic emitting layer; | 74-emitting block; |
| 75-cathode; | 76-cathode block; | 80-encapsulation structure |
| | | layer; |
| 81-first encapsulation layer; | 82-second encapsulation | 83-third encapsulation layer; |
| | layer; | |
| 91-first insulation layer; | 92-second insulation layer; | 93-third insulation layer; |
| 94-fourth insulation layer; | 100-pixel region; | 101-transistor; |
| 102-storage capacitor; | 200-stretch hole region; | 500-stretch hole. |

### DETAILED DESCRIPTION

To make objectives, technical solutions, and advantages of the present disclosure clearer, the embodiments of the present disclosure will be described in detail with reference to the drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to contents described in following implementation modes only. The embodiments in the present disclosure and features in the embodiments may be combined randomly with each other without conflict. In order to keep following description of the embodiments of the present disclosure clear and concise, detailed descriptions about part of known functions and known components are omitted in the present disclosure. The drawings of the embodiments of the present disclosure only involve structures involved in the embodiments of the present disclosure, and other structures may refer to usual designs.

In the drawings, a size of each constituent element, a thickness of a layer, or a region is exaggerated sometimes for clarity. Therefore, one mode of the present disclosure is not necessarily limited to the size, and shapes and sizes of various components in the drawings do not reflect actual scales. In addition, the drawings schematically illustrate ideal examples, and one mode of the present disclosure is not limited to shapes, numerical values, or the like shown in the drawings.

Ordinal numerals such as “first”, “second”, and “third” in the specification are set to avoid confusion of constituent elements, but not to set a limit in quantity.

In the specification, for convenience, wordings indicating directional or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing the constituent elements. Therefore, it is not limited to the wordings described in the specification, which may be appropriately replaced according to situations.

In the specification, unless otherwise specified and defined explicitly, terms “mount”, “mutually connect”, and “connect” should be understood in a broad sense. For example, a connection may be a fixed connection, or a detachable connection, or an integrated connection. It may be a mechanical connection or an electrical connection. It may be a direct connection, or an indirect connection through middleware, or internal communication between two elements. Those of ordinary skill in the art may understand specific meanings of these terms in the present disclosure according to specific situations.

In the specification, a transistor refers to an element which at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that, in the specification, the channel region refers to a region through which the current mainly flows.

In the specification, a first electrode may be the drain electrode, and a second electrode may be the source electrode. Or, the first electrode may be the source electrode, and the second electrode may be the drain electrode. In cases that transistors with opposite polarities are used, a direction of a current is changed during operation of a circuit, or the like, and functions of the “source electrode” and the “drain electrode” are sometimes interchangeable. Therefore, the “source electrode” and the “drain electrode” are interchanged in the specification.

In the specification, an “electrical connection” includes a case that constituent elements are connected together through an element with some electrical effect. The “element with some electrical effect” is not particularly limited as long as electrical signals may be sent and received between the connected constituent elements. Examples of the “element with some electrical effect” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” refers to that a boundary is defined not so strictly and numerical values within process and measurement error ranges are allowed.

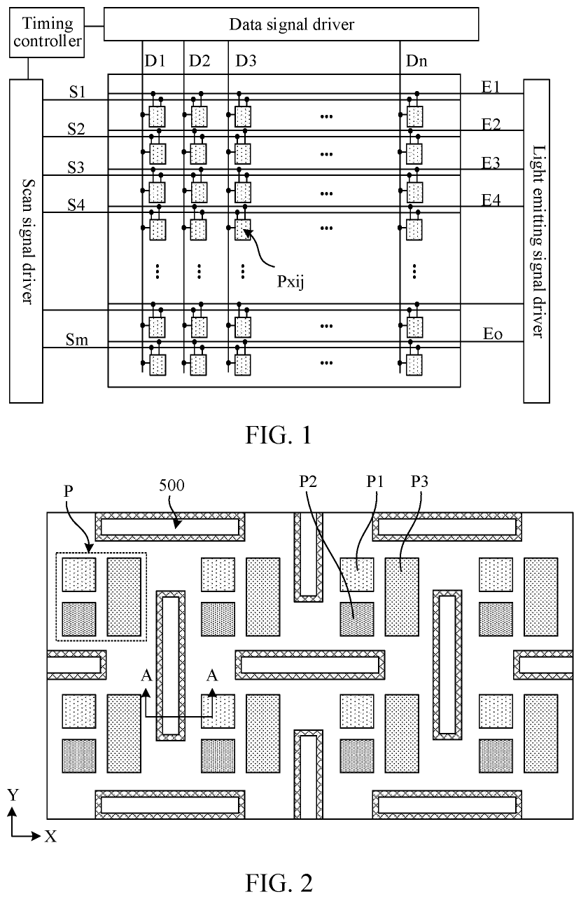

FIG. 1 is a schematic diagram of a structure of a display apparatus. As shown in FIG. 1, an OLED display apparatus may include a timing controller, a data signal driver, a scan signal driver, a light emitting signal driver, and a pixel array. The pixel array may include multiple scan signal lines (S1 to Sm), multiple data signal lines (D1 to Dn), multiple light emitting signal lines (E1 to Eo), and multiple sub-pixels Pxij. In an exemplary implementation mode, the timing controller may provide a gray-scale value and a control signal, which are suitable for a specification of the data signal driver, to the data signal driver, may provide a clock signal, a scan start signal, etc., suitable for a specification of the scan signal driver to the scan signal driver, and may provide a clock signal, an emission stop signal, etc., suitable for a specification of the light emitting signal driver to the light emitting signal driver. The data signal driver may generate data voltages to be provided to data signal lines D1, D2, D3, . . . , and Dn using the gray-scale value and the control signal received from the timing controller. For example, the data signal driver may sample the gray-scale value using a clock signal and apply a data voltage corresponding to the gray-scale value to the data signal lines D1 to Dn by taking a pixel row as a unit, wherein n may be a natural number. The scan signal driver may generate scan signals to be provided to scan signal lines S1, S2, S3, . . . , and Sm by receiving a clock signal, a scan start signal, and the like from the timing controller. For example, the scan signal driver may sequentially provide a scan signal with an on-level pulse to the scan signal lines S1 to Sm. For example, the scan signal driver may be constructed in a form of a shift register and generate a scan signal in a manner of sequentially transmitting a scan start signal provided in a form of an on-level pulse to a next-stage circuit under control of a clock signal, wherein m may be a natural number. The light emitting signal driver may generate an emission signal to be provided to light emitting signal lines E1, E2, E3, . . . , and Eo by receiving the clock signal, the emission stop signal, and the like from the timing controller. For example, the light emitting signal driver may sequentially provide an emission signal with an off-level pulse to the light emitting signal lines E1 to Eo. For example, the light emitting signal driver may be constructed in a form of a shift register and generate a light emitting signal in a manner of sequentially transmitting a light emitting stop signal provided in a form of an off-level pulse to a next-stage circuit under control of a clock signal, wherein o may be a natural number. The pixel array may include multiple sub-pixels Pxij. Each sub-pixel Pxij may be connected to a corresponding data signal line, a corresponding scanning signal line, and a corresponding light emitting signal line. Herein, i and j may be natural numbers. The sub-pixel Pxij may refer to a sub-pixel in which a transistor is connected to an i-th scan signal line and connected to a j-th data signal line.

At present, a flexible OLED display apparatus is uniaxially bent, and an amount of screen deformation is small. By opening a micro-hole on a display substrate, tensile performance of the display substrate may be improved. An island bridge structure may be adopted for a flexible display substrate, in the island bridge structure, a light emitting device is disposed in a pixel region, a hole region including a micro-hole is disposed between pixel regions, and a connection line is disposed between the pixel regions and disposed in a connection bridge region between hole regions. When applying an external force to stretch the display substrate, deformation mainly occurs in a hole region and the connection bridge region, and the light emitting device in the pixel region basically maintains a shape, which may ensure that the light emitting device in the pixel region will not be damaged.

FIG. 2 is a schematic diagram of a planar structure of a display substrate. As shown in FIG. 2, the display substrate may include multiple pixel regions disposed at intervals and the multiple pixel regions may be arranged in a matrix manner. In an exemplary implementation mode, a pixel region may include at least one pixel unit P, and the pixel unit P may include a first sub-pixel P1 that emits light of a first color, a second sub-pixel P2 that emits light of a second color, and a third sub-pixel P3 that emits light of a third color, a sub-pixel may include a pixel drive circuit and a light emitting device. Pixel drive circuits in the first sub-pixel P1, the second sub-pixel P2, and the third sub-pixel P3 are connected with a scan signal line, a data signal line, and a light emitting signal line respectively. The pixel drive circuit is configured to receive a data voltage transmitted by a data signal line under control of a scan signal line and a light emitting signal line, and output a corresponding current to the light emitting device. Each light emitting device in the first sub-pixel P1, the second sub-pixel P2, and the third sub-pixel P3 is connected with a pixel drive circuit of a sub-pixel where the light emitting device is located, and is configured to emit light with corresponding brightness in response to a current output by the pixel drive circuit of the sub-pixel where the light emitting device is located.

In an exemplary implementation mode, the first sub-pixel PI may be a red (R) sub-pixel, the second sub-pixel P2 may be a green (G) sub-pixel, and the third sub-pixel P3 may be a blue (B) sub-pixel. In an exemplary implementation mode, a pixel unit P may include four sub-pixels, such as a red sub-pixel, a green sub-pixel, a blue sub-pixel, and a white sub-pixel. In an exemplary implementation mode, a shape of a sub-pixel in a pixel unit may be a rectangle, a rhombus, a pentagon, or a hexagon. When the pixel unit includes three sub-pixels, the three light emitting units may be arranged side by side horizontally, side by side vertically, or in a manner like a Chinese character “nih”, and when the pixel unit includes four sub-pixels, the four light emitting units may be arranged side by side horizontally, side by side vertically, or in a manner of a square, which is not limited in the present disclosure.

In an exemplary implementation mode, the display substrate may include multiple stretch holes 500 arranged at intervals, the stretch holes 500 are disposed between pixel regions and configured to increase a deformable amount of the display substrate. On a plane perpendicular to the display substrate, a base substrate and a structural film layer in a stretch hole 500 are completely removed to form a through hole structure, or part of the base substrate and the structural film layer in the stretch hole 500 are removed to form a blind hole structure. On a plane parallel to the display substrate, a shape of a stretch hole may include any one or more of following: an “I” shape, a “T” shape, an “L” shape, and an “H” shape, and the present disclosure is not limited herein.

In an exemplary implementation mode, multiple stretch holes 500 may include stretch holes in a first direction and stretch holes in a second direction. The stretch holes in the first direction are strip-shaped holes extending along the first direction X, the stretch holes in the second direction are strip-shaped holes extending along the second direction Y, and the first direction X and the second direction Y intersect. In an exemplary implementation mode, in the first direction X, the stretch holes in the first direction and the stretch holes in the second direction are alternately disposed, a stretch hole in the first direction is disposed between two stretch holes in the second direction, or a stretch hole in the second direction is disposed between two stretch holes in the first direction. In the second direction Y, the stretch holes in the first direction and the stretch holes in the second direction are alternately disposed, a stretch hole in the first direction is disposed between two stretch holes in the second direction, or a stretch hole in the second direction is disposed between two stretch holes in the first direction.

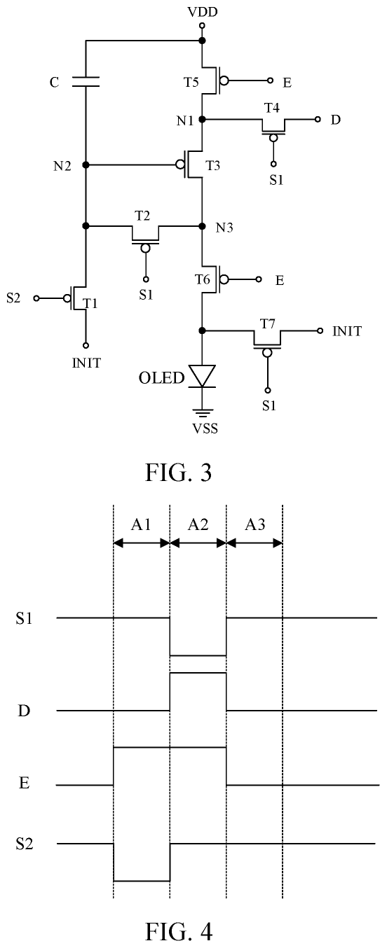

In an exemplary implementation mode, a pixel drive circuit may have a structure of 3TIC, 4TIC, 5TIC, 5T2C, 6TIC, 7TIC, or 8T2C, etc. FIG. 3 is a schematic diagram of an equivalent circuit of a pixel drive circuit. As shown in FIG. 3, the pixel drive circuit may include seven transistors (a first transistor T1 to a seventh transistor T7), a storage capacitor C, and seven signal lines (a first scan signal line S1, a second scan signal line S2, a light emitting signal line E, a data signal line D, an initial signal line INIT, a first power supply line VDD, and a second power supply line VSS).

In an exemplary implementation mode, a first terminal of the storage capacitor C is connected with the first power supply line VDD, and a second terminal of the storage capacitor C is connected with a second node N2, namely the second terminal of the storage capacitor C is connected with a control electrode of the third transistor T3.

A control electrode of the first transistor T1 is connected with the second scan signal line S2, a first electrode of the first transistor T1 is connected with the initial signal line INIT, and a second electrode of the first transistor is connected with the second node N2. When a scan signal with a turn-on level is applied to the second scan signal line S2, the first transistor T1 transmits an initialization voltage to the control electrode of the third transistor T3 so as to initialize a charge amount of the control electrode of the third transistor T3.

A control electrode of the second transistor T2 is connected with the first scan signal line S1, a first electrode of the second transistor T2 is connected with the second node N2, and a second electrode of the second transistor T2 is connected with a third node N3. When a scan signal with a turn-on level is applied to the first scan signal line S1, the second transistor T2 enables the control electrode of the third transistor T3 to be connected with a second electrode of the third transistor T3.

The control electrode of the third transistor T3 is connected with the second node N2, namely the control electrode of the third transistor T3 is connected with the second terminal of the storage capacitor C, a first electrode of the third transistor T3 is connected with a first node N1, and the second electrode of the third transistor T3 is connected with the third node N3. The third transistor T3 may be referred to as a drive transistor, and the third transistor T3 determines an amount of a drive current flowing between the first power supply line VDD and the second power supply line VSS according to a potential difference between the control electrode and the first electrode of the third transistor T3.

A control electrode of the fourth transistor T4 is connected with the first scan signal line S1, a first electrode of the fourth transistor T4 is connected with the data signal line D, and a second electrode of the fourth transistor T4 is connected with the first node N1. The fourth transistor T4 may be referred to as a switching transistor, a scan transistor, etc., and when a scan signal with a turn-on level is applied to the first scan signal line S1, the fourth transistor T4 enables a data voltage of the data signal line D to be input to the pixel drive circuit.

A control electrode of the fifth transistor T5 is connected with the light emitting signal line E, a first electrode of the fifth transistor T5 is connected with the first power supply line VDD, and a second electrode of the fifth transistor T5 is connected with the first node N1. A control electrode of the sixth transistor T6 is connected with the light emitting signal line E, a first electrode of the sixth transistor T6 is connected with the third node N3, and a second electrode of the sixth transistor T6 is connected with a first electrode of a light emitting device. The fifth transistor T5 and the sixth transistor T6 may be referred to as light emitting transistors. When a light emitting signal with a turn-on level is applied to the light emitting signal line E, the fifth transistor T5 and the sixth transistor T6 enable the light emitting device to emit light by forming a drive current path between the first power supply line VDD and the second power supply line VSS.

A control electrode of the seventh transistor T7 is connected with the first scan signal line S1, a first electrode of the seventh transistor T7 is connected with the initial signal line INIT, and a second electrode of the seventh transistor T7 is connected with the first electrode of the light emitting device. When a scan signal with a turn-on level is applied to the first scan signal line S1, the seventh transistor T7 transmits an initialization voltage to the first electrode of the light emitting device so as to initialize a charge amount accumulated in the first electrode of the light emitting device or release a charge amount accumulated in the first electrode of the light emitting device.

In an exemplary implementation mode, a second electrode of the light emitting device is connected with the second power supply line VSS, a signal of the second power supply line VSS is a low-level signal, and a signal of the first power supply line VDD is a high-level signal continuously provided. The first scan signal line S1 is a scan signal line in a pixel drive circuit of a current display row, and the second scan signal line S2 is a scan signal line in a pixel drive circuit of a previous display row. That is, for an n-th display row, the first scan signal line S1 is S(n), and the second scan signal line S2 is S(n−1). The second scan signal line S2 of the current display row and the first scan signal line S1 in the pixel drive circuit of the previous display row are a same signal line, thus signal lines of a display panel may be reduced, so that a narrow bezel of the display panel is achieved.

In an exemplary implementation mode, the first transistor T1 to the seventh transistor T7 may be P-type transistors or N-type transistors. Use of a same type of transistors in a pixel drive circuit may simplify a process flow, reduce process difficulties of a display panel, and improve a product yield. In some possible implementation modes, the first transistor T1 to the seventh transistor T7 may include a P-type transistor and an N-type transistor.

In an exemplary implementation mode, the first scan signal line S1, the second scan signal line S2, the light emitting signal line E, and the initial signal line INIT extend along a horizontal direction, and the second power supply line VSS, the first power supply line VDD, and the data signal line D extend along a vertical direction.

In an exemplary implementation mode, the light emitting device may be an Organic light Emitting Diode (OLED), including a first electrode (anode), an organic emitting layer, and a second electrode (cathode) that are stacked.

FIG. 4 is a working timing diagram of a pixel drive circuit. An exemplary embodiment of the present disclosure will be described below through a working process of the pixel drive circuit shown in FIG. 3. The pixel drive circuit in FIG. 3 includes seven transistors (a first transistor T1 to a seventh transistor T7), one storage capacitor C, and seven signal lines (a data signal line D, a first scan signal line S1, a second scan signal line S2, a light emitting signal line E, an initial signal line INIT, a first power supply line VDD, and a second power supply line VSS), wherein all of the seven transistors are P-type transistors.

In an exemplary implementation mode, the working process of the pixel drive circuit may include following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is the low-level signal, so that the first transistor T1 is turned on, and a signal of the initial signal line INIT is provided to a second node N2 to initialize the storage capacitor C to clear an original data voltage in the storage capacitor. The signals of the first scan signal line S1 and the light emitting signal line E are the high-level signals, so that the second transistor T2, the fourth transistor T4, the fifth transistor T5, the sixth transistor T6, and the seventh transistor T7 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, a second terminal of the storage capacitor C is at a low level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on, so that the data voltage outputted by the data signal line D is provided to the second node N2 through a first node N1, the turned-on third transistor T3, a third node N3, and the turned-on second transistor T2, and the storage capacitor C is charged with a difference between the data voltage outputted by the data signal line D and a threshold voltage of the third transistor T3. A voltage at the second terminal (the second node N2) of the storage capacitor C is Vd-|Vth|, wherein Vd is the data voltage outputted by the data signal line D, and Vth is the threshold voltage of the third transistor T3. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization to ensure that the OLED does not emit light. A signal of the second scan signal line S2 is a high-level signal, so that the first transistor T1 is turned off. A signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is the low-level signal, so that the fifth transistor T5 and the sixth transistor T6 are turned on, and a power voltage outputted by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and a first electrode of the third transistor T3. The voltage of the second node N2 is Vd-|Vth|, so that the drive current of the third transistor T3 is as follows.

I=K*(Vgs−Vth)²=K*[(Vdd−Vd+|Vth|)−Vth]²=K*[(Vdd−Vd]²

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage outputted by the data signal line D, and Vdd is the power voltage outputted by the first power supply line VDD.

In an exemplary implementation mode, in a plane perpendicular to a display substrate, the display substrate may include a drive structure layer disposed on a base substrate, an emitting structure layer disposed on the drive structure layer, and an encapsulation layer disposed on a light emitting element. The drive structure layer includes a pixel drive circuit, the emitting structure layer includes a light emitting device, and the light emitting device is connected with the pixel drive circuit.

FIG. 5 is a schematic diagram of a cross-sectional structure of a display substrate according to an exemplary embodiment of the present disclosure, illustrating a cross-sectional structure at a junction of a pixel region and a stretch hole region, and is a cross-sectional view taken along an A-A direction in FIG. 2. The display substrate may include a pixel region 100 which may include at least one sub-pixel, and a stretch hole region 200 which may include a hole region 50 and a partition region 51 surrounding the hole region 50. In a plane perpendicular to the display substrate, the display substrate may include a base substrate, a structure layer disposed on the base substrate, and an encapsulation structure layer disposed on the structure layer. As shown in FIG. 5, in an exemplary implementation mode, a structure layer of the pixel region 100 may include a drive structure layer 20 disposed on a base substrate 10 and an emitting structure layer 70 disposed on a side of the drive structure layer 20 away from the base substrate. In an exemplary implementation mode, the drive structure layer 20 may include multiple transistors and a storage capacitor constituting a pixel drive circuit. In FIG. 5, only one transistor 101 and one storage capacitor 102 are used as examples. The emitting structure layer 70 may include an anode 71, a pixel definition layer 72, an organic emitting layer 73, and a cathode 75. The anode 71 is connected with a drain electrode of the transistor 101 through a via and a connection electrode 15, the organic emitting layer 73 is connected with the anode 71, and the cathode 75 is connected with the organic emitting layer 73. The organic emitting layer 73 emits light of a corresponding color under drive of the anode 71 and the cathode 75. In an exemplary implementation mode, an encapsulation structure layer 80 of the pixel region 100 is disposed on a side of the emitting structure layer 70 away from the base substrate, and may include a first encapsulation layer 81, a second encapsulation layer 82, and a third encapsulation layer 83 that are stacked. The first encapsulation layer 81 and the third encapsulation layer 83 may be made of inorganic materials, and the second encapsulation layer 82 may be made of an organic material. The second encapsulation layer 82 is disposed between the first encapsulation layer 81 and the third encapsulation layer 83 to ensure that external water vapor cannot enter a light emitting device.

In an exemplary implementation mode, the hole region 50 may include the base substrate 10 and a structure layer 30 disposed on the base substrate 10, and the base substrate 10 is provided with a base substrate hole. The structure layer 30 is provided with a structure hole penetrating through the entire structure layer, and the base substrate hole and the structure hole are communicated. At least part of an inner wall or all of the inner wall of the structure hole may be covered by at least one encapsulation material layer in an encapsulation structure layer. An inner wall of the base substrate hole may include an encapsulation material segment not covered by the encapsulation material layer, or the inner wall of the base substrate hole may include a base substrate material segment covered by the encapsulation material layer and an encapsulation material segment not covered by the encapsulation material layer, wherein the encapsulation material segment is located on a side of the base substrate material segment adjacent to the structure hole. In an exemplary implementation mode, the encapsulation material layer may include the third encapsulation layer 83.

In an exemplary implementation mode, the structure layer 30 of the hole region 50 may include any one or more of following film layers: a first insulation layer, a second insulation layer, a third insulation layer, a fourth insulation layer, and a first planarization layer. In an exemplary implementation mode, the structure layer 30 of the hole region 50 may include a first insulation layer, a second insulation layer, a third insulation layer, a fourth insulation layer, and a first planarization layer that are sequentially stacked along a direction away from the base substrate.

In an exemplary implementation mode, the base substrate hole may be a through hole that penetrates through the entire base substrate 10 or may be a blind hole that does not fully penetrate through the base substrate 10.

In an exemplary implementation mode, the partition region 51 may include the base substrate 10, the structure layer 30 disposed on the base substrate 10, and at least one partition structure disposed on a side of the structure layer 30 away from the base substrate, wherein the partition structure surrounds the hole region 50. In an exemplary implementation mode, the partition structure may include a first partition layer 41 surrounding the hole region 50 and a second partition layer 42 disposed on the first partition layer 41. The first partition layer 41 is provided with a first partition hole surrounding the hole region 50, the second partition layer 42 is provided with a second partition hole surrounding the hole region 50, and the second partition hole and the first partition hole are communicated to form a partition groove 60 surrounding the hole region 50. In an exemplary implementation mode, the second partition layer 42 located around the second partition hole has a protruding part 421 with respect to a sidewall of the first partition hole, and the protruding part 421 and the sidewall of the first partition hole form an inwardly recessed structure.

In an exemplary implementation mode, a width of the second partition hole is smaller than a width of the first partition hole in a direction away from the hole region 50, and an orthographic projection of a profile of the second partition hole on the base substrate is within a range of an orthographic projection of a profile of the first partition hole on the base substrate.

In an exemplary implementation mode, the first partition layer and the second planarization layer in the drive structure layer may be disposed in a same layer and formed through a same patterning process at the same time.

In an exemplary implementation mode, in the partition region 51, the first encapsulation layer 81 covers the partition structure, the second encapsulation layer 82 is disposed on a side of the first encapsulation layer 81 away from the base substrate and fills the partition groove 60, and the third encapsulation layer 83 is disposed on a side of the second encapsulation layer 82 away from the base substrate. The first encapsulation layer 81 covering the partition structure means that the first encapsulation layer 81 covers exposed outer surfaces of the first partition layer 41 and the second partition layer 42 and covers an inner wall of the partition groove 60 to form a complete wrap for the partition structure.

In an exemplary implementation mode, in the hole region 50, the first encapsulation layer 81 is provided with a first encapsulation hole. The first encapsulation hole on the first encapsulation layer 81 is communicated with a structure hole on the structure layer 30, an inner wall of the first encapsulation hole is substantially flush with an inner wall of the structure hole, an orthographic projection of the inner wall of the first encapsulation hole on the base substrate is substantially overlapped with an orthographic projection of the inner wall of the structure hole on the base substrate, and the third encapsulation layer 83 covers the inner wall of the first encapsulation hole.

In an exemplary implementation mode, the hole region 50 also includes an emitting block 74 disposed on a side of the structure layer 30 away from the base substrate. The emitting block is provided with an emitting block hole, the emitting block hole is communicated with the structure hole on the structure layer 30, an inner wall of the emitting block hole is substantially flush with an inner wall of the structure hole, and the third encapsulation layer 83 covers the inner wall of the emitting block hole.

In an exemplary implementation mode, the hole region 50 further includes a cathode block 76 disposed on a side of the emitting block 74 away from the base substrate, and the first encapsulation layer 81 is disposed on a side of the cathode block 76 away from the base substrate. The cathode block 76 is provided with a cathode block hole which is communicated with the emitting block hole, the first encapsulation hole, and the structure hole. An inner wall of the cathode block hole is substantially flush with the inner wall of the emitting block hole, an inner wall of the first encapsulation hole, and the inner wall of the structure hole, and the third encapsulation layer 83 covers the inner wall of the cathode block hole.

In an exemplary implementation mode, an opening size of the base substrate hole may be smaller than an opening size of the structure hole.

Exemplary description is made below through a preparation process of a display substrate. A “patterning process” mentioned in the present disclosure includes coating with a photoresist, mask exposure, development, etching, photoresist stripping, and other treatments for a metal material, an inorganic material, or a transparent conductive material, and includes coating with an organic material, mask exposure, development, and other treatments for an organic material. Deposition may be any one or more of sputtering, evaporation, and chemical vapor deposition. Coating may be any one or more of spray coating, spin coating, and ink-jet printing. Etching may be any one or more of dry etching and wet etching, which is not limited in present disclosure. A “thin film” refers to a layer of thin film made of a material on a base substrate through a process such as deposition and coating. If the “thin film” does not need a patterning process in an entire preparation process, the “thin film” may also be called a “layer”. If the “thin film” needs a patterning process in an entire preparation process, it is called a “thin film” before the patterning process, and called a “layer” after the patterning process. The “layer” after the patterning process includes at least one “pattern”. “A and B are disposed in a same layer” mentioned in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B is within a range of an orthographic projection of A” means that a boundary of the orthographic projection of B falls within a range of a boundary of the orthographic projection of A, or the boundary of the orthographic projection of A is overlapped with the boundary of the orthographic projection of B.

In an exemplary implementation mode, the preparation process of the display substrate may include following operations.

(1) Preparing a base substrate on a glass carrier plate. In an exemplary implementation mode, the base substrate may include a flexible material layer formed on the glass carrier plate. In another exemplary implementation mode, the base substrate may include a first flexible material layer and a second flexible material layer stacked on the glass carrier plate. In yet another exemplary implementation mode, the base substrate may include a first flexible material layer, a first inorganic material layer, a second flexible material layer, and a second inorganic material layer stacked on the glass carrier plate. A material of the first flexible material layer and the second flexible material layer may be Polyimide (PI), Polyethylene Terephthalate (PET), or a polymer soft film subjected to a surface treatment, etc. A material of the first inorganic material layer and the second inorganic material layer may be Silicon Nitride (SiNx) or Silicon Oxide (SiOx), etc., which are used for improving water and oxygen resistance of the base substrate. The first inorganic material layer and the second inorganic material layer may be referred to as barrier layers or buffer layers. In an exemplary implementation mode, taking a laminated structure PI 1/Barrier 1/PI 2/Barrier 2 as an example, a preparation process may include: coating a layer of polyimide on a glass carrier plate 1 first, and forming a first flexible (PI 1) layer after curing the layer of polyimide to form a film; subsequently, depositing a layer of barrier thin film on the first flexible layer to form a first barrier (Barrier 1) layer covering the first flexible layer; then coating a layer of polyimide again on the first barrier layer, and forming a second flexible (PI 2) layer after curing the layer of polyimide to form a film; then depositing a layer of barrier thin film on the second flexible layer to form a second barrier (Barrier 2) layer covering the second flexible layer, so as to complete preparation of the base substrate.

In an exemplary implementation mode, an amorphous Silicon (a-Si) layer may be provided between the first barrier layer and the second inorganic material layer, the base substrate may include a first flexible material layer, a first inorganic material layer, a semiconductor layer, a second flexible material layer, and a second inorganic material layer that are stacked on the glass carrier plate.

In an exemplary implementation mode, in a process of forming the first barrier layer, an inorganic hole may be formed on the first barrier layer through a patterning process, and a position of the inorganic hole may correspond to a position of a through hole to be formed subsequently.

(2) Preparing a pattern of a drive structure layer on a base substrate 10. In an exemplary implementation mode, the drive structure layer may include a transistor and a storage capacitor constituting a pixel drive circuit, and a process of preparing the pattern of the drive structure layer may include: a first insulation thin film and a semiconductor thin film are sequentially deposited on the base substrate 10, and the semiconductor thin film is patterned through a patterning process to form a first insulation layer 91 on the base substrate 10 and a pattern of a semiconductor layer disposed on the first insulation layer 91. The pattern of the semiconductor layer at least includes a first active layer 11.

Then, a second insulation thin film and a first metal thin film are sequentially deposited. The first metal thin film is patterned through a patterning process to form a second insulation layer 92 covering the pattern of the semiconductor layer and a pattern of a first metal layer disposed on the second insulation layer 92. The pattern of the first metal layer at least includes a first gate electrode 12 and first capacitor electrode 21.

Then, a third insulation thin film and a second metal thin film are sequentially deposited, and the second metal thin film is patterned through a patterning process to form a third insulation layer 93 covering the pattern of the first gate metal layer and a pattern of a second metal layer disposed on the third insulation layer 93. The pattern of the second metal layer at least includes a second capacitor electrode 22, and a position of the second capacitor electrode 22 corresponds to a position of the first capacitor electrode 21.

Subsequently, a fourth insulation thin film is deposited, and the fourth insulation thin film is patterned through a patterning process to form a fourth insulation layer 94 covering the pattern of the second metal layer, and multiple vias are provided on the fourth insulation layer 94. The multiple vias may include a first active via and a second active via. The fourth insulation layer 94, the third insulation layer 93, and the second insulation layer 92 in the first active via and the second active via are etched away to expose a source region and a drain region at both ends of the first active layer 11 respectively.

Then, a third metal thin film is deposited and patterned through a patterning process to form a pattern of a third metal layer on the fourth insulation layer 94. The pattern of the third metal layer at least includes a first source electrode 13 and a first drain electrode 14. The first source electrode 13 and the first drain electrode 14 are connected with the source region and the drain region at both ends of the first active layer 11 through the first active via and the second active via respectively.

Subsequently, a first planarization thin film is coated, and the first planarization thin film is patterned through a patterning process to form a first planarization layer 31 covering the pattern of the third metal layer. The first planarization layer 31 is provided with a connection via, and the first planarization layer 31 in the connection via is removed to expose a surface of the first drain electrode 14.

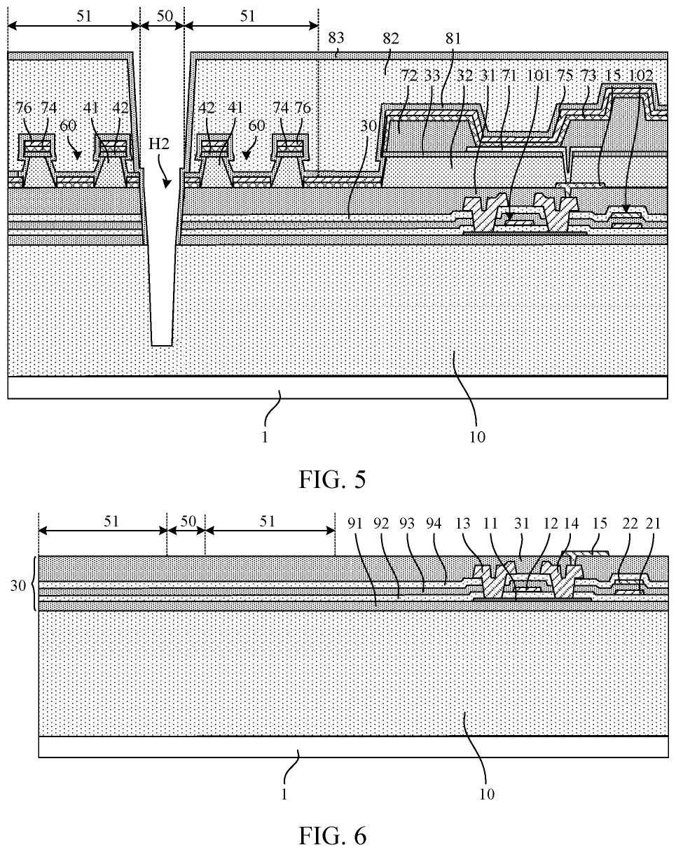

Subsequently, a fourth metal thin film is deposited, and the fourth metal thin film is patterned through a patterning process to form a pattern of a fourth metal layer on the first planarization layer 31. The pattern of the fourth metal layer at least includes a connection electrode 15, and the connection electrode 15 is connected with the first drain electrode 14 through a connection via. The connection electrode 15 is configured to be connected with an anode to be formed subsequently, as shown in FIG. 6, which is a cross-sectional view taken along an A-A direction in FIG. 2.

So far, preparation of a pixel drive circuit is completed, and the pixel drive circuit is illustrated with a transistor and a storage capacitor. In an exemplary implementation mode, the first active layer 11, the first gate electrode 12, the first source electrode 13, and the first drain electrode 14 form a first transistor 101 of the pixel drive circuit, and the first capacitor electrode 21 and the second capacitor electrode 22 form a first storage capacitor 102 of the pixel drive circuit. In an exemplary implementation mode, the first transistor 101 may be a drive transistor in the pixel drive circuit.

In an exemplary implementation mode, the first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, a multi-layer, or a composite layer. The first insulation layer may be referred to as a buffer layer, the second insulation layer and the third insulation layer may be referred to as Gate Insulator (GI) layers, and the fourth insulation layer may be referred to as an Interlayer Dielectric (ILD) layer. The first planarization layer may be made of an organic material such as resin. The first metal layer, the second metal layer, the third metal layer, and the fourth metal layer may be made of a metal material, such as any one or more of silver (Ag), copper (Cu), aluminum (Al), titanium (Ti), and molybdenum (Mo), or an alloy materias of the above metals, such as an Aluminum Neodymium (AlNd) alloy or a Molybdenum Niobium (MoNb) alloy, and may be of a single-layer structure or a multi-layer composite structure, such as Ti/Al/Ti. An active layer may be made of various materials, such as amorphous Indium Gallium Zinc Oxide (a-IGZO), Zinc Oxynitride (ZnON), Indium Zinc Tin Oxide (IZTO), amorphous Silicon (a-Si), polycrystalline Silicon (p-Si), hexathiophene, and polythiophene. That is, the present disclosure is applicable to a transistor manufactured based on an oxide technology, a silicon technology, and an organic matter technology.

In an exemplary implementation mode, the stretch hole region 200 may include at least one hole region 50 and a partition region 51 surrounding the hole region 50. After this patterning process, the hole region 50 and the partition region 51 include the base substrate 10 and the structure layer 30 disposed on the base substrate 10. The structure layer 30 may include the first insulation layer 91, the second insulation layer 92, the third insulation layer 93, the fourth insulation layer 94, and the first planarization layer 31 that are stacked on the base substrate 10.

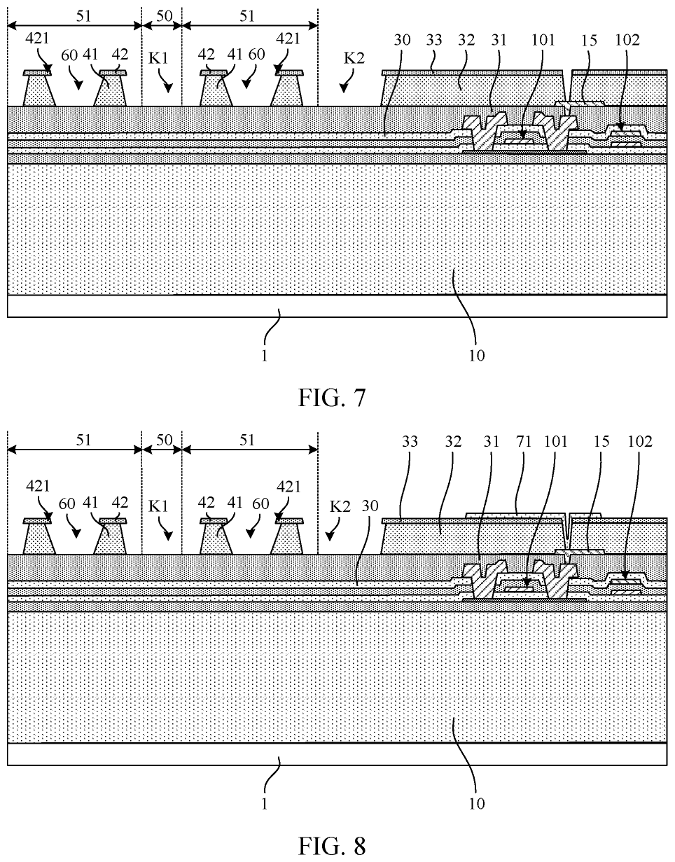

(3) Forming patterns of a second planarization layer and a partition structure. In an exemplary implementation mode, forming the patterns of the second planarization layer and the partition structure may include: a second planarization thin film is first coated on the base substrate on which the aforementioned patterns are formed, an inorganic thin film is then deposited on the second planarization thin film, the inorganic thin film and the second planarization thin film are patterned through a patterning process, and a second planarization layer 32 covering the pattern of the fourth metal layer and an inorganic layer 33 provided on the second planarization layer 32 are formed in a pixel region, and a pattern of the partition structure is formed in a stretch hole region, as shown in FIG. 7, which is a cross-sectional view taken along the A-A direction in FIG. 2.

In an exemplary implementation mode, an anode via is provided on the inorganic layer 33 and the second planarization layer 32 of the pixel region, the inorganic thin film and the second planarization thin film in the anode via are removed to expose a surface of the connection electrode 15, and the anode via is configured to connect the anode formed subsequently with the connection electrode 15 through the via.

In an exemplary implementation mode, the pattern of the partition structure is formed in the partition region 51 in a shape of a ring surrounding the hole region 50. The inorganic thin film and the second planarization thin film on a side of the ring-shaped partition structure close to the hole region 50 are removed, to form a first opening K1 exposing a surface of the first planarization layer 31 of the hole region 50. The inorganic thin film and the second planarization thin film on a side of the ring-shaped partition structure away from the hole region 50 are removed, and a second opening K2 in a shape of a ring is formed between the partition structure and the second planarization layer 32, the second opening K2 exposing a surface of the first planarization layer 31.

In an exemplary implementation mode, in a plane perpendicular to the display substrate, the pattern of the partition structure includes a first partition layer 41 disposed on a side of the first planarization layer 31 away from the base substrate and a second partition layer 42 disposed on a side of the first partition layer 41 away from the base substrate. The ring-shaped first partition layer 41 is provided with a first partition hole, and the ring-shaped second partition layer 42 is provided with a second partition hole. The ring-shaped first partition hole and the ring-shaped second partition hole are communicated with each other, and the first partition hole and the second partition hole form a partition groove 60.

In an exemplary implementation mode, in a plane perpendicular to the base substrate, a cross-sectional shape of the first partition layer 41 may be a trapezoid, and a width of the first partition layer 41 on a side away from the base substrate is smaller than a width of the first partition layer 41 on a side close to the base substrate.

In an exemplary implementation mode, a process of forming the pattern of the partition structure may include: first, a layer of photoresist is coated on the inorganic thin film, and a mask is used for exposing the photoresist. After development, a fully exposed region and an unexposed region are formed. The photoresist in the fully exposed region is removed, the photoresist in the unexposed region is removed, and the photoresist in unexposed regions is retained. Then, the inorganic thin film in the fully exposed region is etched using an etching process to form the ring-shaped second partition layer 42 and the ring-shaped second partition hole provided on the second partition layer 42. Subsequently, the exposed second planarization thin film is continued to be etched to form the ring-shaped first partition layer 41 and the ring-shaped first partition hole provided on the first partition layer 41. The first partition hole and the second partition hole are communicated with each other to form the partition groove 60.

In an exemplary implementation mode, etching may be performed using a dry etching process and using a gas with a relatively large organic/inorganic etching ratio, such as O₂, CF₄, and CHF₃. Due to the relatively large organic/inorganic etching ratio, that is, an etching rate for etching an organic material is greater than an etching rate for etching an inorganic material, when the first partition hole is etched, there is lateral etching in the first partition hole, and the first partition hole on the first partition layer 41 is expanded by a distance relative to the second partition hole of the second partition layer 42 to form the partition groove 60 with a side erosion structure.

In an exemplary implementation mode, in a plane perpendicular to the base substrate, a cross-sectional shape of the first partition hole on the first partition layer 41 is an inverted trapezoid, and a width of an upper opening of the first partition hole on a side away from the base substrate is greater than a width of a lower opening of the first partition hole on a side close to the base substrate. In an exemplary implementation mode, a side of the first partition hole in an inverted trapezoid shape may be arc-shaped.

In an exemplary implementation mode, the second partition layer located around the second partition hole has a protruding part 421 with respect to a sidewall of the upper opening of the first partition hole, and the protruding part 421 and the sidewall of the upper opening of the first partition hole form an inwardly recessed structure.

In an exemplary implementation mode, an opening size of the first partition hole on the first partition layer 41 is smaller than an opening size of an upper opening of the second partition hole on the second partition layer 42, and an orthographic projection of the second partition hole on the base substrate is within a range of an orthographic projection of the upper opening of the first partition hole on the base substrate. Within the partition groove 60, the second partition layer 42 has an edge (protruding part 421) projecting from the upper opening of the first partition hole, forming an “eave” structure. An orthographic projection of a contour line of the second partition hole on the base substrate is within a range of an orthographic projection of a contour line of the upper opening of the first partition hole on the base substrate. In the present disclosure, by arranging the partition groove 60 with the “eave” structure, an organic emitting layer, a cathode, and an optical coupling layer which are subsequently evaporated may be effectively partitioned, and invasion of water and oxygen from the hole region may be effectively blocked.

In an exemplary implementation mode, a width of an edge of the second partition layer 42 protruding from the upper opening of the first partition hole may be about 1 μm to 3 μm, that is, the first partition hole is expanded by 1 μm to 3 μm relative to the second partition hole.

In an exemplary implementation mode, the first partition layer 41, the second partition layer 42 disposed on the first partition layer 41, the first partition hole disposed on the first partition layer 41, and the second partition hole disposed on the second partition layer 42 form the partition structure, the partition structure is formed in the partition region 51 surrounding the hole region 50 and is an annular structure surrounding the hole region 50. In addition, the second partition layer 42 on a side facing the first opening K1 and the second opening K2 may have an “eave” structure protruding from the first partition layer 41.

In an exemplary implementation mode, the second planarization layer may be made of an organic material, such as resin. The inorganic layer may be made of any one or more of SiOx, SiNx, and SiON, may be a single layer, a multi-layer, or a composite layer, and the inorganic layer may be referred to as a Passivation layer (PVX).

So far, preparation of the drive structure layer is completed in the pixel region. In an exemplary implementation mode, the drive structure layer may include the first insulation layer, the semiconductor layer, the second insulation layer, the first metal layer, the third insulation layer, the second metal layer, the fourth insulation layer, the third metal layer, the first planarization layer, the fourth metal layer, the second planarization layer, and the inorganic layer that are stacked.

After this process, the hole region 50 includes the structure layer 30 disposed on the base substrate 10, and the partition region 51 includes the structure layer 30 disposed on the base substrate and the partition structure disposed on a side of the structure layer 30 away from the base substrate, and the partition structure has a shape of a ring surrounding the hole region 50.

(4) Forming a pattern of an anode. In an exemplary implementation mode, the forming the pattern of the anode may include: a conductive thin film is deposited on the base substrate on which the aforementioned patterns are formed, the conductive thin film is patterned through a patterning process to form a pattern of an anode 71, as shown in FIG. 8, which is a cross-sectional view taken along the A-A direction in FIG. 2.

In an exemplary implementation mode, the anode 71 is disposed on the second planarization layer 32 of the pixel region, and the anode 71 is connected with the connection electrode 15 through an anode via. Since the connection electrode 15 is connected with a first drain electrode of the first transistor 101 through a connection via, a connection between the anode 71 and the first transistor 101 through the connection electrode 15 is achieved.

In an exemplary implementation mode, the conductive thin film may be made of a metal material or a transparent conductive material, and the metal material may include any one or more of silver (Ag), copper (Cu), aluminum (Al), titanium (Tl), and molybdenum (Mo), or an alloy material of the above metals, and the transparent conductive material may include Indium Tin Oxide (ITO) or Indium Zinc Oxide (IZO). In an exemplary implementation mode, the conductive thin film may have a single-layer structure or a multi-layer composite structure, such as ITO/Al/ITO.

After this process, structures of the hole region 50 and the partition region 51 are substantially the same as those after a previous patterning process.

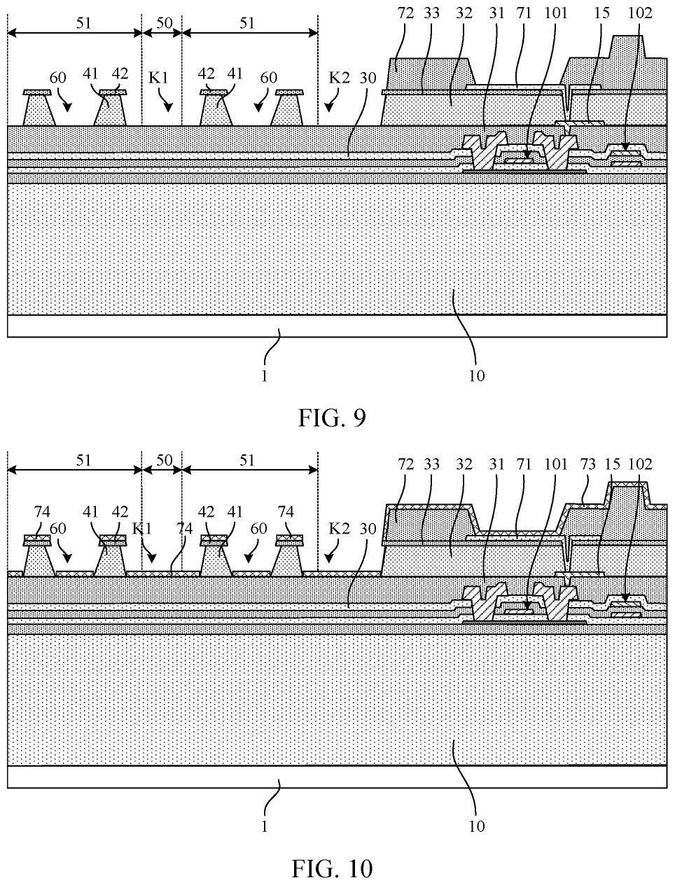

(5) Forming a pattern of a pixel definition layer. In an exemplary implementation mode, the forming the pattern of the pixel definition layer may include: a pixel definition thin film is coated on the base substrate on which the aforementioned patterns are formed; the pixel definition thin film is patterned through a patterning process, and a pattern of a pixel definition layer 72 is formed in the pixel region, as shown in FIG. 9, which is a cross-sectional view taken along the A-A direction in FIG. 2.

In an exemplary implementation mode, a pixel opening is formed on the pixel definition layer 72, and the pixel definition layer in the pixel opening is removed to expose a surface of the anode 71. In an exemplary implementation mode, a pattern of a post spacer may be formed when the pixel definition layer is formed, and the post spacer is configured to support a mask in a subsequent evaporation process. In an exemplary implementation mode, the post spacer may be disposed on an outside of the pixel opening, and the pixel definition layer and the pattern of the post spacer may be formed through a same patterning process through a Half Tone Mask, which is not limited in the present disclosure.

In an exemplary implementation mode, the pixel definition layer may be made of polyimide, acrylic, polyethylene terephthalate, or the like. In a plane parallel to the display substrate, a shape of the pixel opening may be a triangle, a rectangle, a polygon, a circle, an ellipse, or the like. In a plane perpendicular to the display substrate, a cross-sectional shape of the pixel opening may be a rectangle, a trapezoid, or the like, and the present disclosure is not limited herein.

After this process, structures of the hole region 50 and the partition region 51 are substantially the same as those after a previous patterning process.

(6) Forming patterns of an organic emitting layer and an emitting block. In an exemplary implementation mode, forming the patterns of the organic emitting layer and the emitting block may include: on the base substrate on which the aforementioned patterns are formed, patterns of an organic emitting layer 73 and an emitting block 74 are formed by means of vapor deposition or ink-jet printing, as shown in FIG. 10, which is a cross-sectional view taken along the A-A direction in FIG. 2.

In an exemplary implementation mode, in the pixel region, the organic emitting layer 73 is formed on the pixel definition layer 72 and is connected with the anode 71 through the pixel opening.

In an exemplary implementation mode, in the stretch hole region, that is, in a region where the first opening K1, the second opening K2, and the partition structure are located, since the second partition layer 42 has an “eave” structure protruding from the first partition layer 41 and an inner wall of the partition groove 60 has a side erosion structure, an organic emitting material is disconnected at edges of the first opening K1 and the second opening K2, and is disconnected at the “eave” structure of the partition groove 60, and the emitting block 74 is formed on a bottom of the partition groove 60, bottoms of the first opening K1 and the second opening K2, and the second partition layer 42 of the partition structure, and the emitting block 74 and the organic emitting layer 73 are isolated from each other. In the present disclosure, by arranging the partition structure, the organic emitting layer is disconnected, which may cut off a transmission channel of water and oxygen and effectively block invasion of the water and oxygen from the hole region.

In an exemplary implementation mode, the organic emitting layer may include an Emitting Layer (EML), and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation mode, the organic emitting layer may be prepared and formed through evaporation using a Fine Metal Mask (FMM) or an open mask, or prepared and formed using an ink-jet process.

In an exemplary implementation mode, the organic emitting layer may be prepared through a following preparation method. First, a hole injection layer and a hole transport layer are sequentially evaporated using an open mask, and a common layer of the hole injection layer and the hole transport layer is formed in the pixel region. Then, by using a fine metal mask, an electron block layer and a red emitting layer are evaporated in a red sub-pixel, an electron block layer and a green emitting layer are evaporated in a green sub-pixel, and an electron block layer and a blue emitting layer are evaporated in a blue sub-pixel. Electron block layers and emitting layers of adjacent sub-pixels may be overlapped slightly (for example, an overlapping portion accounts for less than 10% of an area of a pattern of a respective emitting layer), or may be isolated. Subsequently, a hole block layer, an electron transport layer, and an electron injection layer are sequentially evaporated using an open mask to form a common layer of the hole block layer, the electron transport layer, and the electron injection layer in the pixel region.

In an exemplary implementation mode, an electron block layer may be used as a micro-cavity adjustment layer of a light emitting device. By designing a thickness of an electron block layer, a thickness of an organic emitting layer between a cathode and an anode may satisfy a design for a length of a micro-cavity. In some exemplary implementation modes, a hole transport layer, a hole block layer, or an electron transport layer in an organic emitting layer may be used as a micro-cavity adjustment layer of a light emitting device, which is not limited in the present disclosure.

In an exemplary implementation mode, an emitting layer may include a host material and a dopant material doped into the host material. A doping ratio of the dopant material of the emitting layer is 1% to 20%. Within a range of the doping ratio, on one hand, the host material of the emitting layer may effectively transfer exciton energy to the dopant material of the emitting layer to excite the dopant material of the emitting layer to emit light; on the other hand, the host material of the emitting layer “dilutes” the dopant material of the emitting layer, thus effectively improving fluorescence quenching caused by collisions between molecules of the dopant material of the emitting layer and collisions between energies, and improving a luminous efficiency and device life. In an exemplary implementation mode, the doping ratio refers to a ratio of a mass of the dopant material to a mass of the emitting layer, that is, a mass percentage. In an exemplary implementation mode, the host material and the dopant material may be co-evaporated through a multi-source evaporation process, so that the host material and the dopant material are uniformly dispersed in the emitting layer. A doping ratio may be adjusted by controlling an evaporation rate of the dopant material or by controlling an evaporation rate ratio of the host material to the dopant material during an evaporation process. In an exemplary implementation mode, a thickness of the emitting layer may be about 10 nm to 50 nm.

In an exemplary implementation mode, a hole injection layer may be made of an inorganic oxide, such as molybdenum oxide, titanium oxide, vanadium oxide, rhenium oxide, ruthenium oxide, chromium oxide, zirconium oxide, hafnium oxide, tantalum oxide, silver oxide, tungsten oxide, or manganese oxide, or may be made of a p-type dopant of a strongly electron withdrawing system and a dopant of a hole transport material. In an exemplary implementation mode, a thickness of the hole injection layer may be about 5 nm to 20 nm.

In an exemplary implementation mode, a hole transport layer may be made of a material with a relatively high hole mobility, such as an aromatic amine compound, and its substituent group may be carbazole, methylfluorene, spirofluorene, dibenzothiophene, or furan. In an exemplary implementation mode, a thickness of the hole transport layer may be about 40 nm to 150 nm.

In an exemplary implementation mode, a hole block layer and an electron transport layer may be made of aromatic heterocyclic compounds, such as benzimidazole derivatives, imidazopyridine derivatives, benzimidazophenanthridine derivatives, and other imidazole derivatives; pyrimidine derivatives, triazine derivatives, and other azine derivatives; quinoline derivatives, isoquinoline derivatives, phenanthroline derivatives, and other compounds containing a nitrogen-containing six-membered ring structure (also including compounds having a phosphine oxide-based substituent on a heterocyclic ring). In an exemplary implementation mode, a thickness of the hole block layer may be about 5 nm to 15 nm, and a thickness of the electron transport layer may be about 20 nm to 50 nm.

In an exemplary implementation mode, an electron injection layer may be made of an alkali metal or a metal, such as lithium fluoride (LiF), ytterbium (Yb), magnesium (Mg), or Calcium (Ca), or a compound of these alkali metals or metals. In an exemplary implementation mode, a thickness of the electron injection layer may be about 0.5 nm to 2 nm.

After this process, the hole region 50 includes the structure layer 30 disposed on the base substrate 10 and the emitting block 74 disposed on a side of the structure layer 30 away from the base substrate. The partition region 51 includes the structure layer 30 disposed on the base substrate 10, the partition structure disposed on a side of the structure layer 30 away from the base substrate, the emitting block 74 disposed on a side of the second partition layer 42 in the partition structure away from the base substrate, and the emitting block 74 disposed on a bottom of the partition groove 60 in the partition structure.

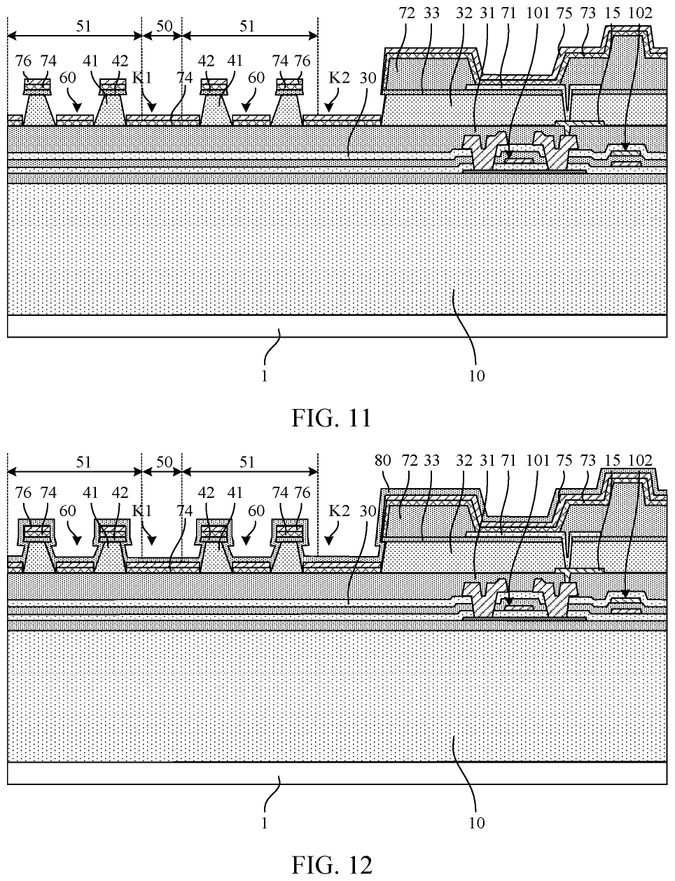

(7) Forming patterns of a cathode and a cathode block. In an exemplary implementation mode, forming a pattern of the cathode may include: patterns of a cathode 75 and a cathode block 76 are formed by means of evaporation on the base substrate on which the aforementioned patterns are formed, as shown in FIG. 11, which is a cross-sectional view taken along the A-A direction in FIG. 2. In an exemplary implementation mode, the cathode may be made of any one or more of magnesium (Mg), silver (Ag), aluminum (A1), copper (Cu), and lithium (Li), or an alloy made of any one or more of the above metals.

In an exemplary implementation mode, the stretchable cathode 75 may be a monolithic structure communicated together. In the pixel region, the cathode 75 is connected with the organic emitting layer 73, so that it is achieved that the organic emitting layer 73 is connected with the anode 71 and the cathode 75 at the same time.

In an exemplary implementation mode, in the stretch hole region, that is, in the region where the first opening K1, the second opening K2, and the partition structure are located, since the second partition layer 42 has an “eave” structure protruding from the first partition layer 41 and the inner wall of the partition groove 60 has a side erosion structure, the cathode is disconnected at edges of the first opening K1 and the second opening K2, and is disconnected at the “eave” structure of the partition groove 60. The cathode block 76 is formed on the bottom of the partition groove 60, the bottoms of the first opening K1 and the second opening K2, and the emitting block 74 of the partition structure, and the cathode block 76 and the cathode 75 are arranged in isolation from each other. In the present disclosure, the cathode is disconnected by arranging the partition structure, which may cut off a transmission channel of water and oxygen and effectively block invasion of the water and oxygen from the hole region.

So far, preparation of the emitting structure layer is completed in the pixel region. In an exemplary implementation mode, the emitting structure layer may include the anode 71, the organic emitting layer 73, and the cathode 75, and the organic emitting layer 73 is disposed between the anode 71 and the cathode 75.

After this process, the hole region 50 includes the structure layer 30 disposed on the base substrate 10, the emitting block 74 disposed on a side of the structure layer 30 away from the base substrate, and the cathode block 76 disposed on a side of the emitting block 74 away from the base substrate. The partition region 51 includes the structure layer 30 disposed on the base substrate 10, the partition structure disposed on a side of the structure layer 30 away from the base substrate, the emitting block 74 disposed on a side of the second partition layer 42 of the partition structure away from the base substrate, the emitting block 74 disposed on the bottom of the partition groove 60 in the partition structure, and the cathode block 76 disposed on a side of the emitting block 74 away from the base substrate.

In an exemplary implementation mode, after forming the patterns of the cathode and the cathode block, an act of forming patterns of an optical coupling layer and an optical coupling block may be included. The optical coupling layer may be a monolithic structure communicated together, disposed on the cathode, and the optical coupling block is disconnected at the “eave” structure and is disposed on the cathode block. In an exemplary implementation mode, a refractive index of the optical coupling layer may be greater than that of the cathode, which facilitates light extraction and increases light extraction efficiency. A material of the optical coupling layer may be an organic material, an inorganic material, or an organic material and an inorganic material, and may be a single layer, a multi-layer, or a composite layer, which is not limited in the present disclosure.

(8) Forming a pattern of a first encapsulation layer. In an exemplary implementation mode, forming the pattern of the first encapsulation layer may include: a first encapsulation thin film 80 is deposited on the base substrate on which the aforementioned patterns are formed, as shown in FIG. 12, which is a cross-sectional view taken along the A-A direction in FIG. 2.

In an exemplary implementation mode, the first encapsulation thin film 80 may be deposited and formed by means of Chemical Vapor Deposition (CVD), plasma enhanced chemical vapor deposition (PECVD), or the like. In the pixel region, the first encapsulation thin film 80 is disposed on a side of the cathode 75 away from the base substrate. In a region where the first opening K1, the second opening K2, and the partition structure are located, the first encapsulation thin film 80 covers an emitting block 74 and a cathode block 76 on the second partition layer 42, covers an emitting block 74 and a cathode block 76 at bottoms of the first opening K1, the second opening K2, and the partition groove 60, and covers sidewalls of the first opening K1, the second opening K2, and the partition groove 60 to form a wrapping structure completely covering the partition structure.

After this process, the hole region 50 includes the structure layer disposed on the base substrate 10, the emitting block 74 disposed on a side of the structure layer away from the base substrate, the cathode block 76 disposed on a side of the emitting block 74 away from the base substrate, and the first encapsulation thin film 80 disposed on a side of the cathode block 76 away from the base substrate.

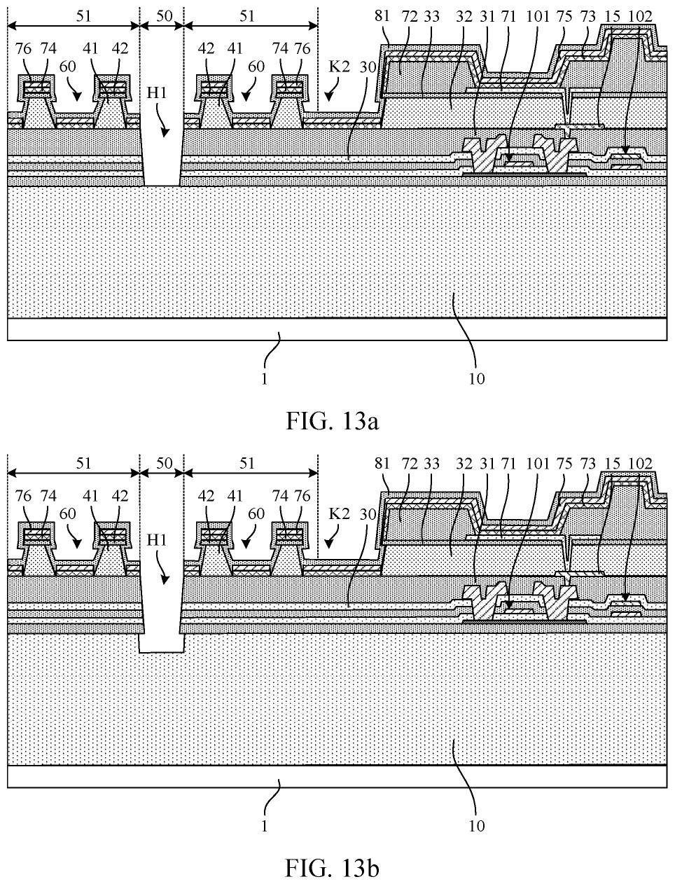

Subsequently, the hole region 50 is etched through a patterning process to form a first encapsulation layer 81 and a pattern of a transition hole H1 located in the hole region 50, as shown in FIGS. 13a and 13b, which are cross-sectional views taken along the A-A direction in FIG. 2.

In an exemplary implementation mode, the first encapsulation thin film 80, the cathode block 76, the emitting block 74, and the structure layer 30 of the hole region 50 are etched, and the first encapsulation layer, the cathode block, the emitting block, the first planarization layer, and a composite insulation layer in the transition hole H1 are removed, a bottom of the transition hole H1 is located at a junction interface of the composite insulation layer and the base substrate, forming the transition hole H1 with a blind hole structure, as shown in FIG. 13a.

In an exemplary implementation mode, the transition hole H1 may include a first encapsulation hole provided on the first encapsulation layer 81, a cathode block hole provided on the cathode block 76, an emitting block hole provided on the emitting block 74, and a structure hole provided on the structure layer 30. The first encapsulation hole, the cathode block hole, the emitting block hole, and the structure hole are communicated with each other. In an exemplary implementation mode, inner walls of the first encapsulation hole, the cathode block hole, the emitting block hole, and the structure hole are substantially flush, and an orthographic projection of an inner wall of the first encapsulation hole on the base substrate, an orthographic projection of an inner wall of the cathode block hole on the base substrate, an orthographic projection of an inner wall of the emitting block hole on the base substrate, and an orthographic projection of an inner wall of the structure hole on the base substrate are substantially overlapped. The structure hole may include a planarization hole provided on the first planarization layer and an insulation hole provided on the composite insulation layer, and the planarization hole and the insulation hole are communicated with each other.

In another exemplary implementation mode, the first encapsulation thin film 80, the cathode block 76, the emitting block 74, and the structure layer 30 of the hole region 50, and the base substrate 10 with a partial thickness are etched, and the first encapsulation layer, the cathode block, the emitting block, the first planarization layer, the composite insulation layer, and the base substrate with the partial thickness in the transition hole H1 are removed, and a bottom of the transition hole H1 is located in the base substrate to form the transition hole H1 with the blind hole structure, as shown in FIG. 13b.

In an exemplary implementation mode, the transition hole H1 may include a first encapsulation hole provided on the first encapsulation layer 81, a cathode block hole provided on the cathode block 76, an emitting block hole provided on the emitting block 74, a structure hole provided on the structure layer 30, and a transition base substrate hole provided on a partial thickness of the base substrate 10. The first encapsulation hole, the cathode block hole, the emitting block hole, the structure hole, and the transition base substrate hole are communicated with each other. In an exemplary implementation mode, inner walls of the first encapsulation hole, the cathode block hole, the emitting block hole, the structure hole, and the transition base substrate hole are substantially flush, an orthographic projection of an inner wall of the first encapsulation hole on the base substrate, an orthographic projection of an inner wall of the cathode block hole on the base substrate, an orthographic projection of an inner wall of the emitting block hole on the base substrate, an orthographic projection of an inner wall of the structure hole on the base substrate, and an orthographic projection of the transition base substrate hole on the base substrate are substantially overlapped.

In an exemplary implementation mode, an inner wall of the transition hole H1 may include an encapsulation material inner wall of the first encapsulation hole, a cathode material inner wall of the cathode block hole, an emitting material inner wall of the emitting block hole, a planarization material inner wall of the planarization hole, an insulation material inner wall of an insulation hole, and a base substrate material inner wall of the transition base substrate hole. The encapsulation material inner wall and the insulation material inner wall may be inorganic materials, the planarization material inner wall and the base substrate material inner wall may be organic materials, the emitting material inner wall may be a small molecular organic material, and the cathode material inner wall may be a metal material.

In an exemplary implementation mode, since etching the transition hole H1 includes etching an inorganic material layer and an organic material layer and an etching rate of etching an organic material is higher than an etching rate of etching an inorganic material, the sidewall of the transition hole H1 forms a step at a junction interface of the base substrate 10 and a composite insulation layer 30. An opening of a blind hole on the base substrate 10 is expanded by a distance relative to a blind hole on the composite insulation layer, and the composite insulation layer in the inner wall of the transition hole H1 has an “eave” structure protruding from the base substrate.

In an exemplary implementation mode, an opening size of the transition base substrate hole on the base substrate may be larger than an opening size of the structure hole on the structure layer, an orthographic projection of a profile of the structure hole on the structure layer on a glass base substrate is located within a range of an orthographic projection of a profile of the transition base substrate hole on the base substrate on the glass base substrate.

In an exemplary implementation mode, in the partition region 51, the first encapsulation layer 81 covers an exposed outer surface of the partition structure and the inner wall of the partition groove 60 to form a complete wrap for the partition structure. The first encapsulation layer 81 completely wraps the partition structure, which ensures encapsulation integrity, not only effectively isolates water and oxygen from the hole region, but also forms a pinning point on the encapsulation layer by the partition groove, which may prevent peeling failure of an edge of a film layer.

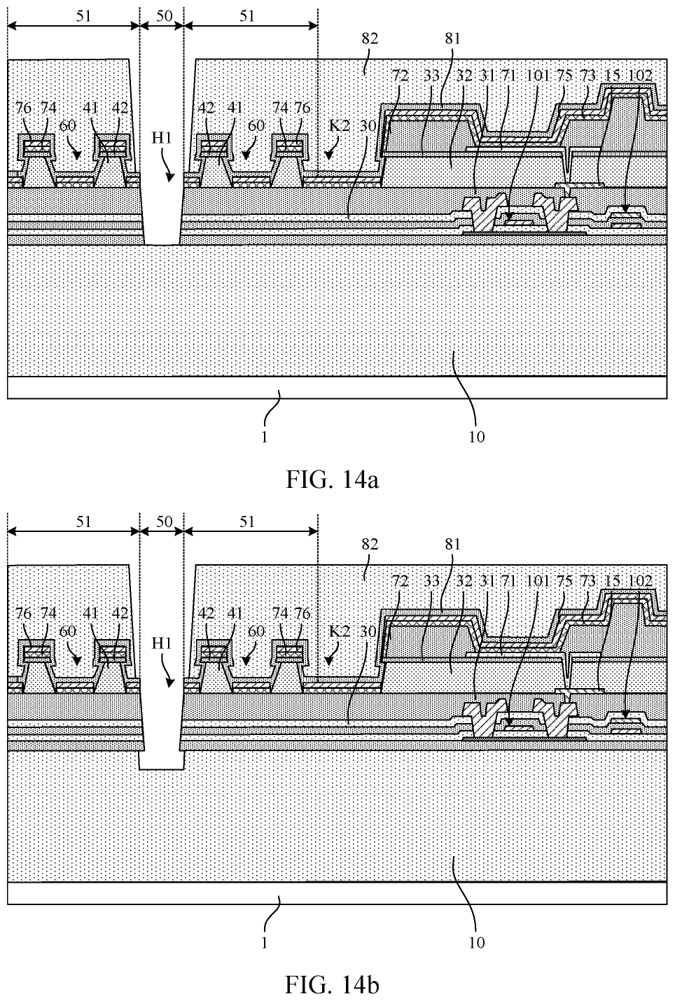

(9) Forming a pattern of a second encapsulation layer. In an exemplary implementation mode, forming the pattern of the second encapsulation layer may include: on the base substrate on which the aforementioned patterns are formed, a second encapsulation thin film is formed using an ink-jet printing or coating process, the second encapsulation thin film is patterned, the second encapsulation thin film in the hole region 50 and near the hole region 50 is removed, and a second encapsulation layer 82 is formed after curing into a film, as shown in FIGS. 14a and 14b, which are cross-sectional views taken along the A-A direction in FIG. 2.

In an exemplary implementation mode, the second encapsulation layer 82 is disposed on the first encapsulation layer 81 outside the hole region 50 and completely fills the partition groove 60 to form an inorganic material that wraps the partition structure. The second encapsulation layer 82 in the hole region 50 is removed to expose the transition hole H1, and the second encapsulation layer 82 in a region near the hole region is removed to expose a surface of the first encapsulation layer 81.

In an exemplary implementation mode, the pattern of the second encapsulation layer may be formed using an ink-jet printing+coating process. A first organic material layer is firstly formed in the pixel region by means of ink-jet printing, and then a second organic material layer is formed in an isolation region using a coating process, and the second organic material layer wraps an outer surface of the partition structure and fills the partition groove. In an exemplary implementation mode, materials of the first organic material layer and the second organic material layer may be the same, or may be different.

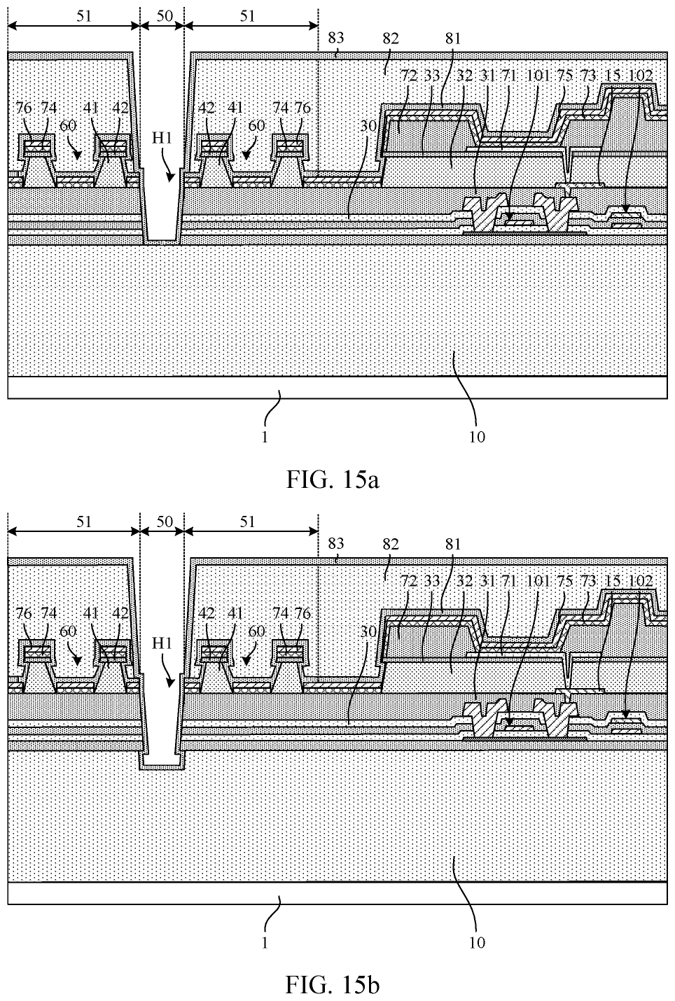

(10) Forming a pattern of a third encapsulation layer. In an exemplary implementation mode, the forming the pattern of the third encapsulation layer may include: on the base substrate on which the aforementioned patterns are formed, a third encapsulation thin film is deposited to form a third encapsulation layer 83, as shown in FIG. 15a and FIG. 15b, which are cross-sectional views taken along the A-A direction in FIG. 2.

In an exemplary implementation mode, the third encapsulation layer 83 may be deposited and formed by means of Chemical Vapor Deposition (CVD), plasma enhanced chemical vapor deposition (PECVD), or the like. In an region outside the hole region 50, the third encapsulation layer 83 is disposed on the second encapsulation layer 82, in the hole region 50, the third encapsulation layer 83 covers the inner wall of the transition hole H1 to form a complete wrap for the transition hole H1.

In an exemplary implementation mode, the third encapsulation layer 83 covering the inner wall of the transition hole H1 means that the third encapsulation layer 83 covers an inner sidewall of an encapsulation hole, an inner sidewall of the cathode block hole, an inner sidewall of the emitting block hole, an inner sidewall of the planarization hole, and an inner sidewall and a bottom of the insulation hole, as shown in FIG. 15a. In another exemplary implementation mode, the third encapsulation layer 83 covering the inner wall of the transition hole H1 means that the third encapsulation layer 83 covers an inner sidewall of an encapsulation hole, an inner sidewall of the cathode block hole, an inner sidewall of the emitting block hole, an inner sidewall of the planarization hole, an inner sidewall of the insulation hole, an inner sidewall of the transition base substrate hole, and a bottom of the transition base substrate hole, as shown in FIG. 15b. Thus, an inorganic material inner wall and an organic material inner wall in the transition hole H1 are both covered by the third encapsulation layer 83 of an inorganic material, thereby effectively isolating water and oxygen from the hole region.

So far, preparation of the encapsulation structure layer is completed. In an exemplary implementation mode, the encapsulation structure layer may include the first encapsulation layer 81, the second encapsulation layer 82, and the third encapsulation layer 83 that are stacked. The first encapsulation layer and the third encapsulation layer may be made of any one or more of Silicon Oxide (SiOx), Silicon Nitride (SiNx), and Silicon Oxynitride (SiON), and may be a single layer, a multi-layer, or a composite layer, which may ensure that external water and oxygen cannot enter the emitting structure layer. The second encapsulation layer may be made of a resin material, which plays a role of covering each film layer of the display substrate, so as to improve structural stability and planarization. In a region outside the hole region 50, an encapsulation layer forms a laminated structure of inorganic material/organic material/inorganic material. In the hole region 50, the third encapsulation layer (encapsulation material layer) in the encapsulation structure layer completely wraps the inner wall of the transition hole H1, ensuring encapsulation integrity and effectively isolating water and oxygen from the hole region and the outside world.

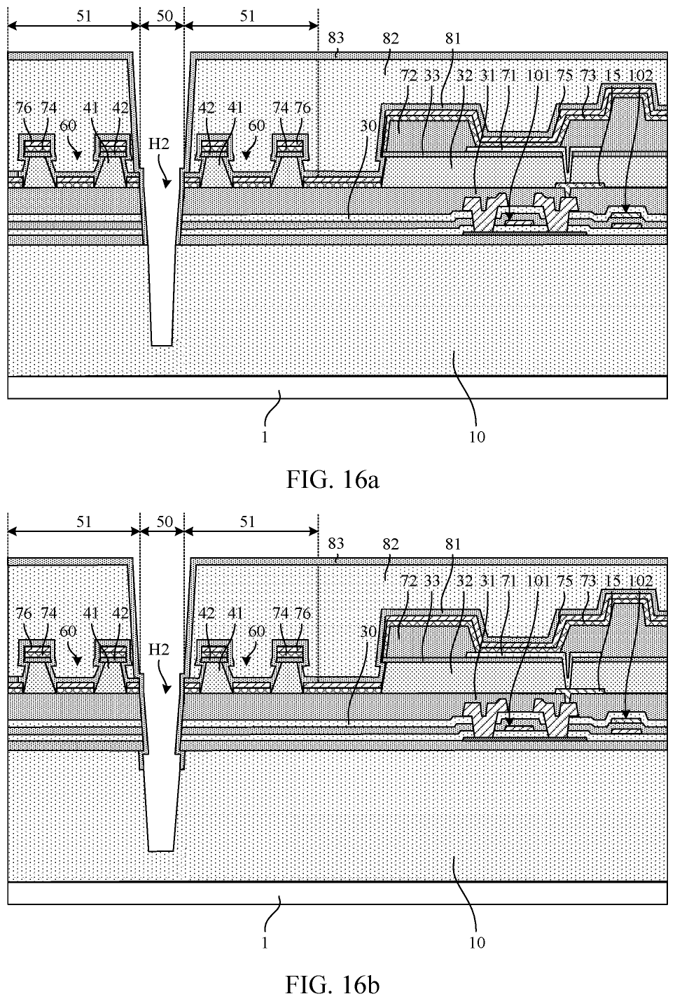

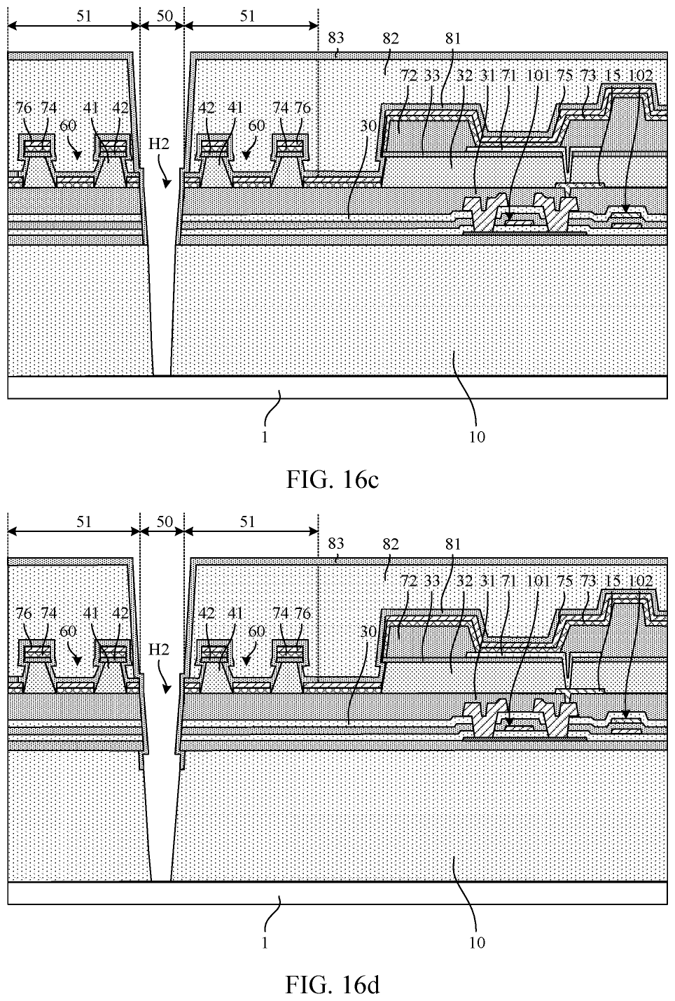

(11) Forming a pattern of a stretch hole. In an exemplary implementation mode, forming the pattern of the stretch hole may include: on the base substrate on which the aforementioned patterns are formed, the transition hole H1 is etched through a patterning process to form a pattern of a stretch hole H2, as shown in FIGS. 16a, 16b, 16c, and 16d, which are cross-sectional views taken along the A-A direction in FIG. 2.

In an exemplary implementation mode, for an etching process of the stretch hole H2, etching is essentially performed along an outer surface of the third encapsulation layer 83 covering the transition hole H1. First, the third encapsulation layer 83 at the bottom of the transition hole H1 is etched off to form a third encapsulation hole, and then the base substrate 10 is continued to be etched to form the base substrate hole, wherein the base substrate hole, the third encapsulation hole, and the transition hole form the stretch hole H2. In an exemplary implementation mode, forming the stretch hole through an etching process may be understood as opening the third encapsulation hole on the third encapsulation layer and opening the base substrate hole on the base substrate, wherein the transition hole, the third encapsulation hole, and the base substrate hole are communicated with each other. An inner wall of the transition hole, an inner wall of the third encapsulation hole, and an inner wall of the base substrate hole are substantially flush, and an orthographic projection of the inner wall of the transition hole on the base substrate, an orthographic projection of the inner wall of the third encapsulation hole on the base substrate, and an orthographic projection of the inner wall of the base substrate hole on the base substrate are substantially overlapped.

For the stretch hole H2 formed by etching in this way, an inner wall of the stretch hole H2 may include a base substrate material segment not covered by the encapsulation material layer (third encapsulation layer 83) and an encapsulation material segment covered by the encapsulation material layer. The encapsulation material segment is located on a side of the base substrate hole close to the structure hole, that is, the base substrate material segment is located on a side of the encapsulation material segment close to the glass base substrate 1, so that a peeling interface between the display substrate and the glass base substrate only has a base substrate material, which effectively avoids a situation that the display substrate cannot be separated from the glass base substrate in a subsequent peeling process, avoids a pulling crack in a peeling process, and effectively ensures an encapsulation effect of the display substrate.

In an exemplary implementation mode, the stretch hole may be a blind hole, i.e., the base substrate within the stretch hole is partially removed and a bottom of the stretch hole exposes a surface of the base substrate, as shown in FIGS. 16a and 16b. In an exemplary implementation mode, the third encapsulation layer 83 covers only inner walls of the first encapsulation hole, the cathode block hole, the emitting block hole, and the structure hole, and the inner wall of the base substrate hole is all the base substrate material segment not covered by the third encapsulation layer 83, as shown in FIG. 16a. In another exemplary implementation mode, the third encapsulation layer 83 not only covers inner walls of the first encapsulation hole, the cathode block hole, the emitting block hole, and the structure hole, but also covers part of an inner wall of the base substrate hole. The inner wall of the base substrate hole includes an encapsulation material segment covered by the third encapsulation layer 83 and a base substrate material segment not covered by the third encapsulation layer 83, and the encapsulation material segment is located on a side of the base substrate material segment close to the structure layer, as shown in FIG. 16b.

In an exemplary implementation mode, the stretch hole may be a through hole, i.e. the base substrate within the stretch hole is completely removed and a bottom of the stretch hole exposes a surface of a peeled base substrate, as shown in FIGS. 16c and 16d. In an exemplary implementation mode, the third encapsulation layer 83 only covers inner walls of the first encapsulation hole, the cathode block hole, the emitting block hole, and the structure hole, and the inner wall of the base substrate hole is all the base substrate material segment not covered by the third encapsulation layer 83, as shown in FIG. 16c. In another exemplary implementation mode, the third encapsulation layer 83 not only covers inner walls of the first encapsulation hole, the cathode block hole, the emitting block hole, and the structure hole, but also covers part of an inner wall of the base substrate hole. The inner wall of the base substrate hole includes an encapsulation material segment covered by the third encapsulation layer 83 and a base substrate material segment not covered by the third encapsulation layer 83, and the encapsulation material segment is located on a side of the base substrate material segment close to the structure layer, as shown in FIG. 16d.

In an exemplary implementation mode, an opening size of the base substrate hole is smaller than an opening size of the structure hole, and an orthographic projection of a profile of the opening on the base substrate hole on the base substrate is within a range of an orthographic projection of a profile of the opening on the structure hole on the base substrate.

Or, the inner wall of the base substrate hole may include a base substrate material segment covered by the encapsulation material layer and an encapsulation material segment not covered by the encapsulation material layer, wherein the encapsulation material segment is located on a side of the base substrate material segment close to the structure hole.

In an exemplary implementation mode, in a plane parallel to the display substrate, a width of the stretch hole may be about 5 μm to 15 μm.

In an exemplary implementation mode, after preparation of the encapsulation structure layer is completed, a Touch Structure layer (TSP) may be formed on THE encapsulation structure layer, and the touch structure layer may include a touch electrode layer, or include a touch electrode layer and a touch insulation layer, which is not limited in the present disclosure.

In a subsequent process, the display substrate and the glass base substrate may be peeled off through a laser peeling process, and then process such as attaching a back film and cutting may be included, which is not limited in the present disclosure.

In a display substrate provided with a stretch hole, there is a problem that a film layer cannot be effectively peeled off during a peeling process, which leads to encapsulation failure. It was found from researches that the film layer could not be effectively peeled off during the peeling process, which, to a certain extent, was caused by a residual inorganic encapsulation layer in the stretch hole. In a current etching process of a hole region, it is difficult to completely etch away a structure layer in the hole region, especially an inorganic encapsulation layer directly deposited on a glass base substrate, so that a part of the inorganic encapsulation layer attached to the glass base substrate will remain at a bottom of the hole region. When there is the part of the inorganic encapsulation layer remaining at the bottom of the hole region, due to strong adhesion between the inorganic encapsulation layer and the glass base substrate, the part of the inorganic encapsulation layer cannot be separated from the glass base substrate during a peeling process, and the inorganic encapsulation layer remaining on the glass base substrate will cause a pulling crack in an encapsulation layer, which will lead to encapsulation failure.

As may be seen from that the structure of the display substrate and the preparation process thereof in the exemplary embodiment of the present disclosure, in the exemplary embodiment of the present disclosure, a transition hole is formed after a first encapsulation layer is formed, and a stretch hole is formed by covering an inner wall of the transition hole with a third encapsulation layer, a base substrate material segment that is not covered by an encapsulation material layer is formed in a base substrate hole in the stretch hole, so that a peeling interface between the display substrate and a glass base substrate only has a base substrate material and no inorganic material. Since the base substrate material may be separated from the glass base substrate without damage, a situation that a film layer of the display substrate cannot be separated from the glass base substrate is avoided, and a pulling crack in a peeling process is avoided, thus effectively ensuring encapsulation reliability of the display substrate. In the exemplary embodiment of the present disclosure, a partition structure is provided in a partition region surrounding a stretch hole, and the partition structure is wrapped by an encapsulation structure layer, thereby water and oxygen from a hole region are cut off to a maximum extent and an encapsulation effect is improved. The preparation process of the display substrate in the exemplary embodiment of the present disclosure has good process compatibility, simple process achievement, easy implementation, a high production efficiency, a low production cost, and a high yield.

The structure of the display substrate and the preparation process thereof in the exemplary embodiment of the present disclosure are merely illustrative. In an exemplary implementation mode, a corresponding structure may be changed and a patterning process may be increased or decreased according to actual needs. For example, multiple sequentially sleeved partition structures may be provided on an outside of the hole region, and the present disclosure is not limited herein.

The present disclosure further provides a preparation method of a display substrate. The display substrate includes a pixel region and a stretch hole region, the pixel region includes at least one sub-pixel, and the stretch hole region includes at least one hole region and a partition region surrounding the hole region. In an exemplary implementation mode, the preparation method may include: forming a base substrate, a structure layer disposed on the base substrate, and an encapsulation structure layer disposed on the structure layer, wherein the partition region includes at least a partition structure, and the partition structure surrounds the hole region; and forming a stretch hole in the hole region, wherein the stretch hole includes a base substrate hole disposed on the base substrate and a structure hole penetrating through the structure layer, the base substrate hole is communicated with the structure hole, at least a portion of an inner wall of the structure hole is covered by at least one encapsulation material layer in the encapsulation structure layer, and an inner wall of the base substrate hole includes a base substrate material segment that is not covered by the encapsulation material layer.

In an exemplary implementation mode, the inner wall of the base substrate hole further includes an encapsulation material segment covered by the encapsulation material layer, and the encapsulation material segment is located on a side of the base substrate material segment close to the structure hole.

In an exemplary implementation mode, the base substrate hole includes a through hole penetrating through the base substrate, or includes a blind hole not penetrating through the base substrate.

In an exemplary implementation mode, the forming the stretch hole in the hole region may include: forming an encapsulation structure layer and a transition hole; wherein the encapsulation structure layer includes a first encapsulation layer, a second encapsulation layer, and a third encapsulation layer as the encapsulation material layer that are stacked; the transition hole is located in the hole region, the first encapsulation layer and the structure layer in the transition hole are removed, and the third encapsulation layer covers an inner wall of the transition hole; and etching the transition hole to form the stretch hole; wherein the stretch hole includes the transition hole and the base substrate hole disposed on the base substrate, the base substrate hole and the transition hole are communicated, and the inner wall of the base substrate hole includes a base substrate material segment not covered by the third encapsulation layer.

In an exemplary implementation mode, materials of the first encapsulation layer and the third encapsulation layer include inorganic materials, and a material of the second encapsulation layer includes an organic material; the forming the encapsulation structure layer and the transition hole may include: forming the first encapsulation layer covering the structure layer and the partition structure; forming the transition hole in the hole region through a patterning process, wherein the first encapsulation layer and the structure layer in the transition hole are removed; forming the second encapsulation layer, wherein the second encapsulation layer is disposed on a side of the first encapsulation layer in the pixel region and the partition region away from the base substrate, or, a first organic material layer in the second encapsulation layer is disposed on a side of the first encapsulation layer in the pixel region away from the base substrate, and a second organic material layer in the second encapsulation layer is disposed on a side of the first encapsulation layer in the partition region away from the base substrate; and forming the third encapsulation layer as the encapsulation material layer, wherein the third encapsulation layer is provided on a side of the second encapsulation layer away from the base substrate, and the third encapsulation layer covers the inner wall of the transition hole.

The present disclosure provides a preparation method of a display substrate. A base substrate material segment not covered by an encapsulation material layer is formed in a base substrate hole in a stretch hole, so that a peeling interface between the display substrate and a glass base substrate only has a base substrate material, a situation that a film layer of the display substrate cannot be separated from the glass base substrate is avoided, a pulling crack in a peeling process is avoided, and an encapsulation effect of the display substrate is effectively ensured. The preparation method of the display substrate of the present disclosure has good process compatibility, simple process achievement, easy implementation, a high production efficiency, a low production cost, and a high yield.

The present disclosure further provides a display apparatus including the display substrate of the aforementioned embodiments. The display apparatus may be any product or component with a display function, such as a mobile phone, a tablet computer, a television, a display, a laptop computer, a digital photo frame, or a navigator.

Although implementation modes disclosed in the present disclosure are as above, the described contents are only implementation modes used for convenience of understanding the present disclosure and are not intended to limit the present disclosure. Any skilled in the art to which the present disclosure pertains, without departing from the spirit and scope disclosed in the present disclosure, may make any modifications and changes in a form and details of implementation. However, the scope of patent protection of the present application should still be subject to the scope defined by the appended claims.

1. A display substrate, comprising a pixel region and a stretch hole region, wherein the pixel region comprises at least one sub-pixel, and the stretch hole region comprises at least one hole region and a partition region surrounding the hole region; the display substrate comprises a base substrate, a structure layer disposed on the base substrate, and an encapsulation structure layer disposed on a side of the structure layer away from the base substrate, the partition region comprises at least one partition structure, the partition structure surrounds the hole region; the hole region comprises a base substrate hole disposed on the base substrate and a structure hole penetrating through the structure layer, the base substrate hole is communicated with the structure hole, at least a portion of an inner wall of the structure hole is covered by at least one encapsulation material layer in the encapsulation structure layer, and an inner wall of the base substrate hole comprises a base substrate material segment that is not covered by the encapsulation material layer.

2. The display substrate according to claim 1, wherein the inner wall of the base substrate hole further comprises an encapsulation material segment covered by the encapsulation material layer, wherein the encapsulation material segment is located on a side of the base substrate material segment close to the structure hole.

3. The display substrate according to claim 1, wherein the base substrate hole comprises a through hole penetrating through the base substrate, or comprises a blind hole not penetrating through the base substrate.

4. The display substrate according to claim 1, wherein the partition structure comprises a first partition layer and a second partition layer disposed on a side of the first partition layer away from the base substrate, the first partition layer is provided with a first partition hole surrounding the hole region, the second partition layer is provided with a second partition hole surrounding the hole region, and the second partition hole is communicated with the first partition hole to form a partition groove; the second partition layer located around the second partition hole has a protruding part relative to a sidewall of the first partition hole, and the protruding part and the sidewall of the first partition hole form an inwardly recessed structure.

5. The display substrate according to claim 1, wherein the partition structure is disposed between the structure layer and the encapsulation structure layer.

6. The display substrate according to claim 1, wherein an opening size of the base substrate hole is smaller than an opening size of the structure hole.

7. The display substrate according to claim 1, wherein the encapsulation structure layer comprises a first encapsulation layer, the first encapsulation layer covers the structure layer and the partition structure, an encapsulation hole is provided on the first encapsulation layer of the hole region, and the encapsulation hole is communicated with the structure hole.

8. The display substrate according to claim 7, wherein an orthographic projection of an inner wall of the encapsulation hole on the base substrate and an orthographic projection of an inner wall of the structure hole on the base substrate are substantially overlapped.

9. The display substrate according to claim 7, wherein the encapsulation structure layer further comprises a second encapsulation layer; the second encapsulation layer is disposed on a side of the first encapsulation layer of the pixel region away from the base substrate, or the second encapsulation layer is disposed on a side of the first encapsulation layer of the pixel region and the partition region away from the base substrate.

10. The display substrate according to claim 9, wherein the encapsulation structure layer further comprises a third encapsulation layer as the encapsulation material layer; the third encapsulation layer is disposed on a side of the second encapsulation layer away from the base substrate, the third encapsulation layer covers inner walls of the structure hole and the encapsulation hole, and the third encapsulation layer does not cover the base substrate material segment of the base substrate hole.

11. The display substrate according to claim 10, wherein the third encapsulation layer covers a part of an inner wall of the base substrate hole, and an encapsulation material segment covered by the third encapsulation layer is formed in the base substrate hole, or the third encapsulation layer does not cover the inner wall of the base substrate hole, and the inner wall of the base substrate hole is all the base substrate material segment.

12. The display substrate according to claim 10, wherein an emitting block is provided on a side of the structure layer of the hole region away from the base substrate, an emitting block hole is provided on the emitting block, the emitting block hole is communicated with the structure hole, and the third encapsulation layer covers an inner wall of the emitting block hole.

13. The display substrate according to claim 12, wherein a cathode block is disposed on a side of the emitting block of the hole region away from the base substrate, the first encapsulation layer is disposed on a side of the cathode block away from the base substrate, a cathode block hole is provided on the cathode block, the cathode block hole is communicated with the emitting block hole and the encapsulation hole, and the third encapsulation layer covers an inner wall of the cathode block hole.

14. A display apparatus, comprising the display substrate according to claim 1.

15. A preparation method of a display substrate, the display substrate comprises a pixel region and a stretch hole region, the pixel region comprises at least one sub-pixel, and the stretch hole region comprises at least one hole region and a partition region surrounding the hole region; the preparation method comprises:
forming a base substrate, a structure layer disposed on the base substrate, and an encapsulation structure layer disposed on the structure layer, wherein the partition region comprises at least a partition structure, and the partition structure surrounds the hole region;
forming a stretch hole in the hole region, wherein the stretch hole region comprises a base substrate hole disposed on the base substrate and a structure hole penetrating through the structure layer, the base substrate hole is communicated with the structure hole, at least a portion of an inner wall of the structure hole is covered by at least one encapsulation material layer in the encapsulation structure layer, and an inner wall of the base substrate hole comprises a base substrate material segment that is not covered by the encapsulation material layer.

16. The preparation method according to claim 15, wherein the inner wall of the base substrate hole further comprises an encapsulation material segment covered by the encapsulation material layer, and the encapsulation material segment is located on a side of the base substrate material segment close to the structure hole.

17. The preparation method according to claim 15, wherein the base substrate hole comprises a through hole penetrating through the base substrate, or comprises a blind hole not penetrating through the base substrate.

18. The preparation method according to claim 15, wherein the forming the stretch hole in the hole region comprises:
forming an encapsulation structure layer and a transition hole; the encapsulation structure layer comprises a first encapsulation layer, a second encapsulation layer, and a third encapsulation layer as the encapsulation material layer that are stacked; the transition hole is located in the hole region, the first encapsulation layer and the structure layer in the transition hole are removed, and the third encapsulation layer covers an inner wall of the transition hole; and
etching the transition hole to form a stretch hole; the stretch hole comprises the transition hole and a base substrate hole disposed on the base substrate, the base substrate hole and the transition hole are communicated, and an inner wall of the base substrate hole comprises a base substrate material segment not covered by the third encapsulation layer.

19. The preparation method according to claim 18, wherein materials of the first encapsulation layer and the third encapsulation layer comprise inorganic materials, and a material of the second encapsulation layer comprises an organic material; the forming the encapsulation structure layer and the transition hole comprises:
forming a first encapsulation layer, wherein the first encapsulation layer covers the structure layer and the partition structure;
forming a transition hole in the hole region through a patterning process, wherein the first encapsulation layer and the structure layer in the transition hole are removed;
forming a second encapsulation layer, wherein the second encapsulation layer is disposed on a side of the first encapsulation layer of the pixel region and the partition region away from the base substrate, or, a first organic material layer in the second encapsulation layer is disposed on a side of the first encapsulation layer of the pixel region away from the base substrate, and a second organic material layer in the second encapsulation layer is disposed on a side of the first encapsulation layer of the partition region away from the base substrate; and
forming a third encapsulation layer as the encapsulation material layer, wherein the third encapsulation layer is provided on a side of the second encapsulation layer away from the base substrate, and the third encapsulation layer covers the inner wall of the transition hole.

20. The display substrate according to claim 2, wherein the encapsulation structure layer comprises a first encapsulation layer, the first encapsulation layer covers the structure layer and the partition structure, an encapsulation hole is provided on the first encapsulation layer of the hole region, and the encapsulation hole is communicated with the structure hole.
